(19) United States
(12) Patent Application Publication
(10) Pub. No.: US 2025/0309178 A1
(43) Pub. Date: Oct. 2, 2025

(54) SEMICONDUCTOR DEVICE

(71) Applicant: Rohm Co., Ltd., Kyoto-shi (JP)

(72) Inventors: Junsuke SATAKE, Kyoto-shi (JP); Tomohira KIKUCHI, Kyoto-shi (JP); Hiroaki MATSUBARA, Kyoto-shi (JP)

(21) Appl. No.: 19/085,503

(22) Filed: Mar. 20, 2025

(30) Foreign Application Priority Data
Mar. 26, 2024 (JP) 2024-050356
Mar. 26, 2024 (JP) 2024-050357

(51) Int. Cl. H01L 23/00; H01L 23/495; H01L 25/065

(52) U.S. Cl. CPC H01L 24/48; H01L 23/49555; H01L 23/49575; H01L 25/0655; H01L 2224/48108; H01L 2224/4814; H01L 2224/48245; H01L 2224/48451; H01L 2224/4846; H01L 2924/1426

(57) ABSTRACT

A semiconductor device includes a first semiconductor element, a second semiconductor element, a first lead, a second lead, a first wire, and a first bump-stacked body. The first lead is electrically connected to the first semiconductor element. The second lead is electrically connected to the second semiconductor element and is separated from the first lead. The first wire electrically connects the first semiconductor element and the second semiconductor element. The bump-stacked body includes a plurality of bumps stacked in a thickness direction of the first semiconductor element. The first wire includes a first end overlapping with the first semiconductor element and a second end overlapping with the second semiconductor element in the thickness direction. The first bump-stacked body is located between the first semiconductor element and the first end or between the second semiconductor element and the second end.

### FIELD

This disclosure relates to semiconductor devices.

### BACKGROUND

Inverters are used in electric vehicles and home appliances. The inverters, for example, may include a semiconductor device provided with a switching element such as an IGBT (Insulated Gate Bipolar Transistor) or a MOSFET (Metal Oxide Semiconductor Field Effect Transistor). Such a semiconductor device includes a control element and a drive element. The inverter supplies a control signal received from an engine control unit (ECU) to the control element of the semiconductor device. The control element of the semiconductor device converts the signal into a PWM (Pulse Width Modulation) control signal. The converted control signal is transmitted to the drive element of the semiconductor device. The drive element switches a plurality of (e.g., six,) switching elements based on the PWM control signal. Through the switching of the six switching elements, direct current (DC) power supplied from an on-vehicle battery is converted into three-phase alternating current (AC) power, which is suitable for the motor driving.

In the semiconductor device, the control element may operate at a low source voltage (about 5 volts), while the drive element may operate at a high source voltage (about 600 volts or higher). Thus, a signal between multiple elements with different power supply voltages needs to be transmitted via an insulating element. For example, JP-A-2009-49035 discloses an intelligent power module as an example of a semiconductor device with an insulating element. The module includes a control circuit, an insulating transformer, and an arm circuit (upper or lower arm). The insulating transformer transmits a signal between the control circuit and the arm circuit. The control circuit includes a CPU or a system LSI with a CPU. The arm circuit includes a gate driver IC. The CPU of the control circuit supplies a PWM signal for gate drive. The PWM signal for gate drive controls the conduction or non-conduction of switching elements. The PWM signal for gate drive is transmitted to the arm circuit in an insulated environment via the insulating transformer. Based on the PWM signal for gate drive, the gate driver IC in the arm circuit supplies a gate signal. The gate signal is transmitted to a control terminal of the switching elements to switch the switching elements.

### BRIEF DESCRIPTION OF THE DRAWINGS

FIG. 1 is a plan view of a semiconductor device according to a first embodiment.

FIG. 2 is a plan view, in which the sealing resin is shown as imaginary lines in FIG. 1.

FIG. 3 is a front view of the semiconductor device according to the first embodiment.

FIG. 4 is a right-side view of the semiconductor device according to the first embodiment.

FIG. 5 is a left-side view of the semiconductor device according to the first embodiment.

FIG. 6 is a sectional view taken along line VI-VI of FIG. 2.

FIG. 7 is a sectional view taken along line VII-VII of FIG. 2.

FIG. 8 is an enlarged view of a part of FIG. 7.

FIG. 9 is a sectional view of the semiconductor element according to the first embodiment.

FIG. 10 is a flowchart showing an example of a method for manufacturing the semiconductor device according to the first embodiment.

FIG. 11 is a plan view illustrating a manufacturing step of the semiconductor device shown in FIG. 10.

FIG. 12 is a plan view illustrating a manufacturing step of the semiconductor device shown in FIG. 10.

FIG. 13 is a plan view illustrating a manufacturing step of the semiconductor device shown in FIG. 10.

FIG. 14 is a plan view illustrating a manufacturing step of the semiconductor device shown in FIG. 10.

FIG. 15 is a plan view illustrating a manufacturing step of the semiconductor device shown in FIG. 10.

FIG. 16 is a plan view illustrating a manufacturing step of the semiconductor device shown in FIG. 10.

FIG. 17 is a plan view illustrating a manufacturing step of the semiconductor device shown in FIG. 10.

FIG. 18 is a sectional view of the semiconductor device according to the first embodiment.

FIG. 19 is a sectional view of a part of a semiconductor device according to a first variation of the first embodiment.

FIG. 20 is a plan view of a second variation of the first embodiment, in which the sealing resin is shown as imaginary lines.

FIG. 21 is a sectional view of a semiconductor device according to a second embodiment.

FIG. 22 is a sectional view of a part of the semiconductor device according to the second embodiment.

FIG. 23 is a sectional view of the semiconductor device according to a first variation of the second embodiment.

FIG. 24 is a sectional view of a part of the semiconductor device according to the first variation of the second embodiment.

FIG. 25 is a plan view of a semiconductor device according to a third embodiment, in which the sealing resin is shown as imaginary lines.

FIG. 26 is a sectional view taken along line XXVI-XXVI of FIG. 25.

FIG. 27 is an enlarged view of a part of FIG. 26.

FIG. 28 is a sectional view of a part of a semiconductor device according to a first variation of the third embodiment.

FIG. 29 is a sectional view of a part of a semiconductor device according to a fourth embodiment.

FIG. 30 is a sectional view of a part of a semiconductor device according to a first variation of the fourth embodiment.

FIG. 31 is a sectional view of a part of a semiconductor device according to a fifth embodiment.

FIG. 32 is an enlarged view of a part of FIG. 31.

FIG. 33 is a sectional view of a part of a semiconductor device according to a first variation of the fifth embodiment.

FIG. 34 is a sectional view of a part of a semiconductor device according to a second variation of the fifth embodiment.

FIG. 35 is a sectional view of a part of a semiconductor device according to a third variation of the fifth embodiment.

FIG. 36 is a plan view of a semiconductor device according to a sixth embodiment, in which the sealing resin is shown as imaginary lines.

FIG. 37 is a partial sectional view taken along line XXXVII-XXXXVII of FIG. 36.

FIG. 38 is a sectional view of a part of a semiconductor device according to a first variation of the sixth embodiment.

FIG. 39 is a plan view of a semiconductor device according to a seventh embodiment, in which the sealing resin is shown as imaginary lines.

FIG. 40 is a partial sectional view taken along line XL-XL of FIG. 39.

FIG. 41 is a sectional view of a part of a semiconductor device according to a first variation of the seventh embodiment.

FIG. 42 is an overview diagram of a vehicle comprising the semiconductor device of the present disclosure.

### DETAILS

Embodiments of the present invention will be described below with reference to the accompanying drawings.

Descriptions in the present disclosure corresponds to the followings, unless otherwise specifically noted. The expression “An object A is formed in an object B”, and “An object A is formed on an object B” imply the situation where “the object A is formed directly in or on the object B”, and “the object A is formed in or on the object B, with something else interposed between the object A and the object B”. The expression “An object A is disposed in an object B”, and “An object A is disposed on an object B” imply the situation where “the object A is disposed directly in or on the object B”, and “the object A is disposed in or on the object B, with something else interposed between the object A and the object B”. The expression “An object A overlaps with an object B as viewed in a certain direction” implies the situation where “the object A overlaps with the entirety of the object B”, and “the object A overlaps with a part of the object B”. The expression “an object A (or the material thereof) contains a material C” includes “an object A (or the material thereof) is made of a material C” and “an object A (or the material thereof) is mainly composed of a material C”. The expression “A surface A faces (a first side or a second side) in a direction B” is not limited to the situation where the angle of the surface A to the direction B is 90° and includes the situation where the surface A is inclined with respect to the direction B. The expression “a shape of an object A is equal to a shape of an object B” and “a dimension C is equal to a dimension D” include at least the case where there is a difference generally recognized as a manufacturing error.

In the description of the present disclosure, a thickness direction z, a first direction x and a second direction y that are orthogonal to each other are referred to. The thickness direction z is a thickness direction of the first semiconductor element 11, for example. The expression “as viewed in the thickness direction z” may correspond to “in plan view”. One side of the thickness direction z may be referred to as “up” and the other as “down”. In the present disclosure, the terms “upside”, “downside”, “above”, “below”, “top surface” and “bottom surface” indicate the relative positional relationship of each component in the thickness direction z, and do not necessarily define the relationship with respect to the direction of gravity.

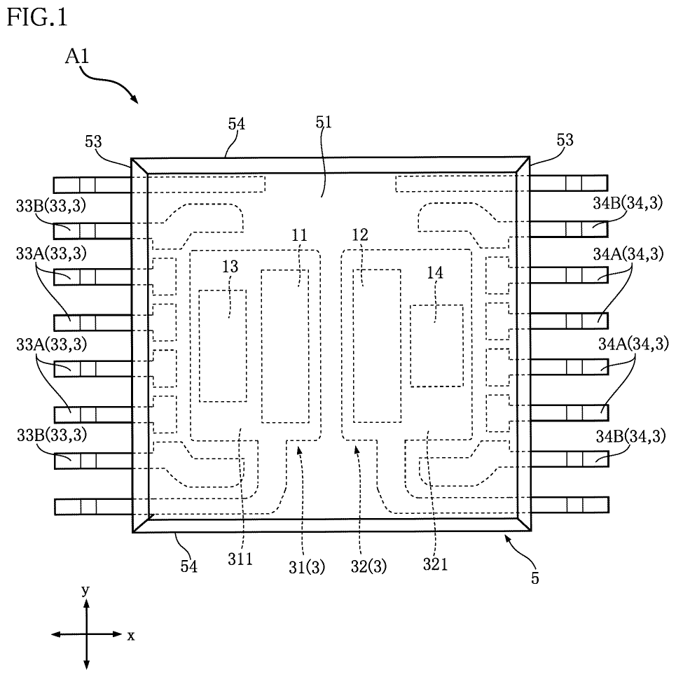

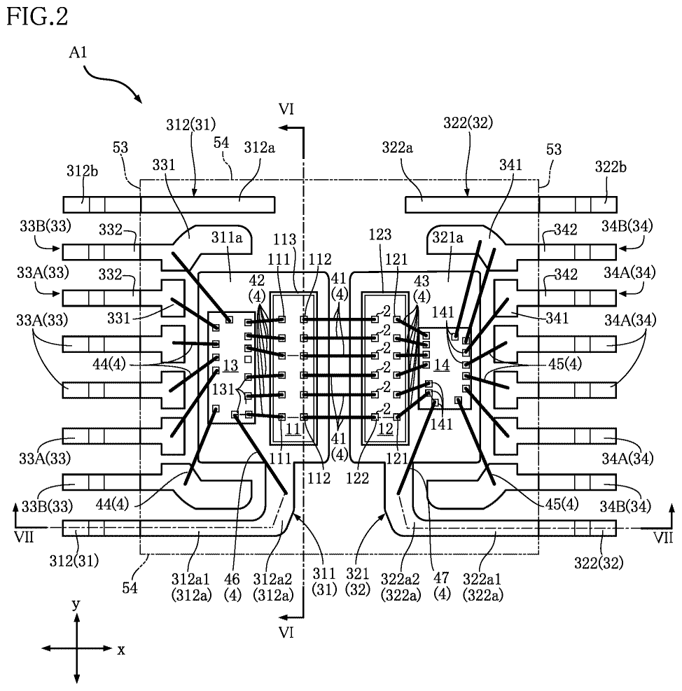

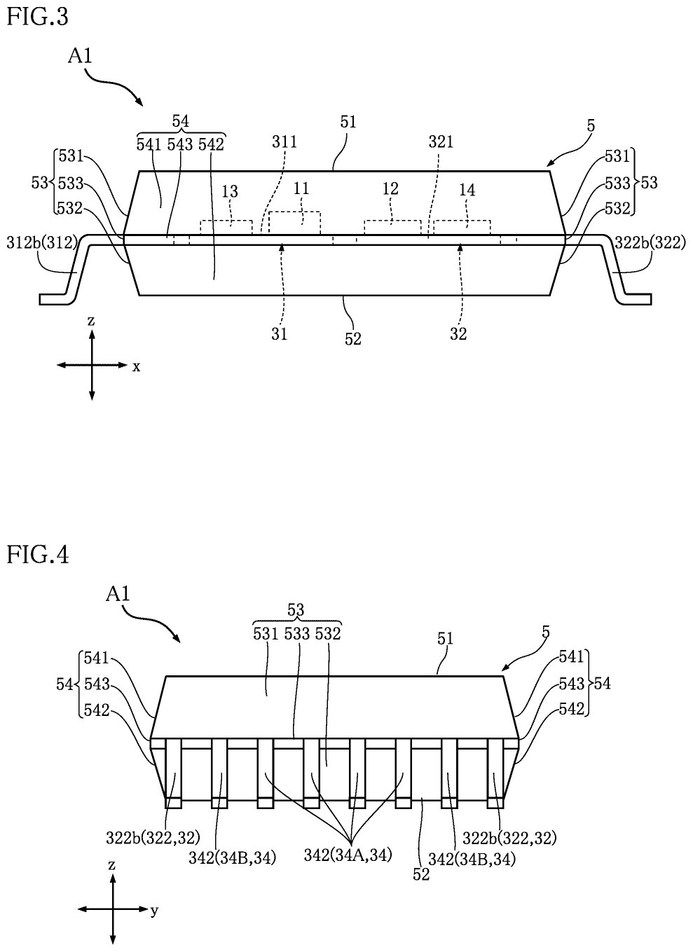

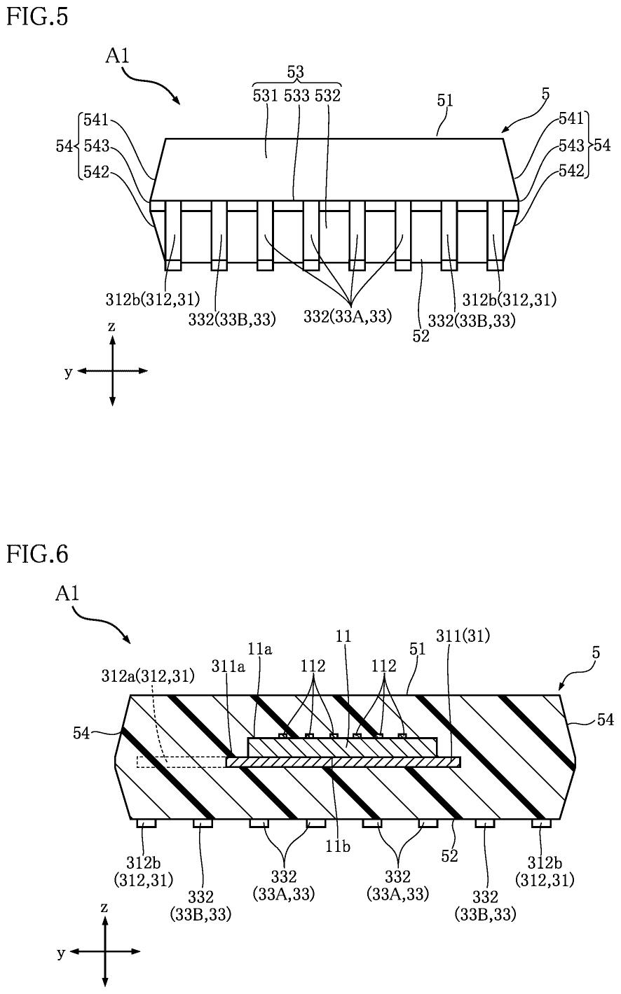

First, a semiconductor device A1 according to a first embodiment of the present disclosure will be described with reference to FIGS. 1 to 9. As shown in these figures, the semiconductor device A1 includes a first semiconductor element 11, a second semiconductor element 12, a third semiconductor element 13, a fourth semiconductor element 14, a plurality of bump-stacked bodies 2, a conductive support member 3, a plurality of connection members 4 and a sealing resin 5. Each of the plurality of bump-stacked bodies 2 includes a plurality of bumps 21 stacked on top of one another. The conductive support member 3 includes a first lead 31, a second lead 32, a plurality of third leads 33, and a plurality of fourth leads 34. The plurality of connection members 4 include a plurality of first wires 41, a plurality of second wires 42, a plurality of third wires 43, a plurality of fourth wires 44, a plurality of fifth wires 45, a sixth wire 46 and a seventh wire 47. The number of sixth wire 46 and the seventh wire 47 is not limited to one.

The semiconductor device A1 is surface mountable on a circuit board of an inverter of, for example, an electric vehicle or hybrid vehicle. The semiconductor device A1 controls the switching operation of switching elements such as IGBTs or MOSFETs. The semiconductor device A1 is of an SOP (Small Outline Package) package type, as understood from FIGS. 1 and 3 to 5. However, the package type of the semiconductor device A1 is not limited to an SOP.

Each of the first semiconductor element 11, the second semiconductor element 12, the third semiconductor element 13, and the fourth semiconductor element 14 may form the functional core of the semiconductor device A1. In the first direction x, the first semiconductor element 11 and the second semiconductor element 12 are located between the third semiconductor element 13 and the fourth semiconductor element 14. More specifically, in the first direction x, the first semiconductor element 11 is located between the second semiconductor element 12 and the third semiconductor element 13, and the second semiconductor element 12 is between the first semiconductor element 11 and the fourth semiconductor element 14. In plan view, each of the first semiconductor element 11, the second semiconductor element 12, the third semiconductor element 13 and the fourth semiconductor element 14 is rectangular in shape with the long side in the second direction y.

The third semiconductor element 13 may be a controller (control element) of a gate driver to drive a switching element such as an IGBT or a MOSFET. Specifically, the third semiconductor element 13 includes a circuit for converting a control signal input from an ECU or the like into a PWM control signal, a send circuit for sending the PWM control signal to the first semiconductor element 11, and a receive circuit for receiving an electric signal from the first semiconductor element 11.

In the illustrated example, the third semiconductor element 13 includes a third obverse face 13a and a third reverse face 13b. The third obverse face 13a and the third reverse face 13b are spaced apart from each other in the thickness direction z. The third obverse face 13a is provided with a plurality of pads 131. The composition of each pad 131 includes aluminum (Al), for example. The third reverse face 13b faces the first lead 31.

The fourth semiconductor element 14 may be a gate driver (drive element) to drive the switching element. Specifically, the fourth semiconductor element 14 includes a receive circuit for receiving a PWM control signal, a drive circuit for driving a switching element based on the signal, and a sending circuit for sending electric signals to the third semiconductor element 13. The electric signals include, for example, an output signal from a temperature sensor, which may be disposed near the motor.

In the illustrated example, the fourth semiconductor element 14 includes a fourth obverse face 14a and a fourth reverse face 14b. The fourth obverse face 14a and the fourth reverse face 14b are spaced apart from each other in the thickness direction z. The fourth obverse face 14a is provided with a plurality of pads 141. The composition of each pad 141 includes aluminum, for example. The fourth reverse face 14b faces the second lead 32.

The first semiconductor element 11 and the second semiconductor element 12 may transmit a PWM control signal and other electric signals in an insulated environment (i.e., these may be insulating elements). The first semiconductor element 11 and the second semiconductor element 12 may be of inductive or capacitive types. An example of an inductive type is an insulating transformer. An example of a capacitive type is a capacitor. Alternatively, the first semiconductor element 11 and the second semiconductor element 12 may be a photocoupler.

In the illustrated example, the first semiconductor element 11 includes an first obverse face 11a and a first reverse face 11b, a first seal ring 113, a first functional portion 115, a first semiconductor substrate 110, a laminated structure 117, and a wiring portion 118.

The first obverse face 11a and the first reverse face 11b are spaced apart from each other in the thickness direction z. The first obverse face 11a is provided with a plurality of pads 111 and a plurality of pads 112. The composition of each of pads 111 and 112 includes aluminum, for example. The first reverse face 11b faces the first lead 31.

The first seal ring 113 is formed along each of the four outer edges of the first semiconductor element 11 in plan view and surrounds the periphery of the circuit forming region. The first seal ring 113 includes a portion that protrudes from the first obverse face 11a in the thickness direction z. The first seal ring 113 is made of copper (Cu) or aluminum, for example.

The first functional portion 115 is electrically connected to the pads 111 and 112. The first functional portion 115 includes internally a plurality of first upper windings 115a and a plurality of first lower windings 115b. More specifically, the first functional portion 115 includes a plurality of pairs comprising one first upper winding 115a and one first lower winding 115b. the first lower windings 115b are electrically connected to the respective pads 111. The first upper windings 115a are electrically connected to the respective pads 112. As an example, the pairs of the first upper winding 115a and the first lower winding 115b are arranged along the longitudinal direction (second direction y) of the first semiconductor element 11.

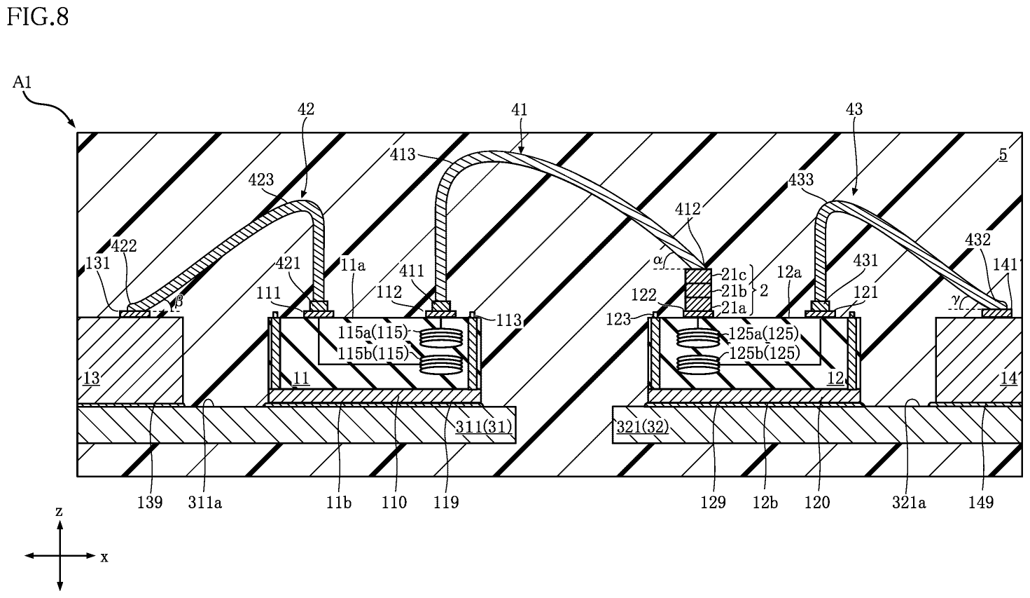

FIG. 8 shows one of the pairs of the first upper winding 115a and the first lower winding 115b. Each of the first upper winding 115a and the first lower winding 115b is provided in a planar spiral shape. In each pair of the first upper winding 115a and the first lower winding 115b, the first upper winding 115a is spaced apart from and faces the first lower winding 115b in the thickness direction z. In each pair of the first upper winding 115a and the first lower winding 115b, the first upper winding 115a is magnetically coupled to the first lower winding 115b. The magnetic coupling is induced by the third semiconductor element 13. In other words, the third semiconductor element 13 inductively couples the first upper windings 115a and the first lower windings 115b to transmit electric signals in an insulated environment.

As the first semiconductor substrate 110, an Si (silicon) substrate, an SiC (silicon carbide) substrate or the like can be utilized. Instead of the first semiconductor substrate 110, an insulating substrate such as a ceramic substrate or a resin substrate can be utilized for the first semiconductor element 11. The first seal ring 113 stands on the first semiconductor substrate 110. In the present embodiment, the potential of the first seal ring 113 is the same (or generally same) as the potential of the first semiconductor substrate 110.

The laminated structure 117 is formed on the first semiconductor substrate 110. The first seal ring 113 penetrates through the laminated structure 117 in the thickness direction z. The laminated structure 117 includes a plurality of insulative layers 1171. The insulative layers 1171 are stacked on the top surface of the first semiconductor substrate 110. The insulative layers 1171 each include a stacked structure of a lower etching stopper film and an upper interlayer insulating film, except for the lowest insulative layer 1171 that is in contact with the top surface of the first semiconductor substrate 110. The lowest insulative layer 1171 may consist only of an interlayer insulating film. As the etching stopper film, a silicon nitride (SiN) film, a silicon carbide (SiC) film, or a silicon carbonitride (SiCN) film can be utilized. As the interlayer insulating film, a silicon oxide (SiO₂) film can be utilized. The dimension in the thickness direction z of each insulative layer 1171 is not limited, but is 2.4 μm, for example. The thickness of each insulative layer 1171 may be different from each other.

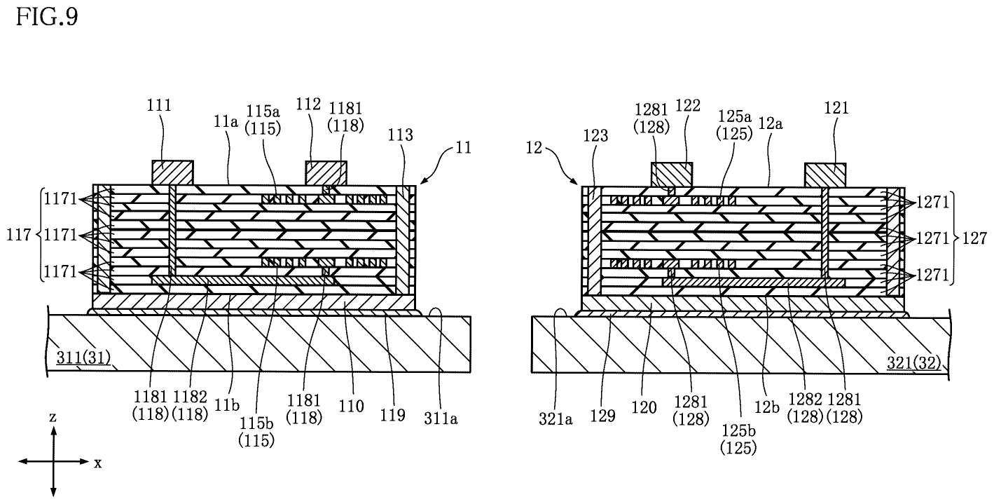

FIG. 9 shows an example of the internal structure of the first semiconductor element 11. In the illustrated first semiconductor element 11, the laminated structure 117 includes twelve insulative layers 1171 disposed in a stacked arrangement along the z direction. From the first semiconductor substrate 110, the first lower winding 115b is formed on the fourth insulative layer 1171 and the first upper winding 115a is formed on the eleventh insulative layer 1171, with six insulative layers 1171 sandwiched between the first upper winding 115a and the first lower winding 115b. In other words, the first upper winding 115a and the first lower winding 115b face each other, with one or more insulative layers 1171 interposed therebetween.

The number of insulative layers 1171 is not limited to the illustrated example and may be changed according to the magnitude of the voltage applied to each of the pads 111 and pads 112. The number of insulative layers 1171 may involve a trade-off relationship between the thickness (the dimension in the thickness direction z) and the dielectric strength in the first semiconductor element 11. The greater the number of insulative layers 1171 between the first upper winding 115a and the first lower winding 115b, the greater the dielectric strength in the first semiconductor element 11, but the thickness of the first semiconductor element 11 is also increases. On the other hand, the smaller the number of insulative layers 1171 between the first upper winding 115a and the first lower winding 115b, the less the dielectric strength in the first semiconductor element 11, but the thickness of the first semiconductor element 11 decreases.

In the present embodiment, in view of the relationship between the dielectric strength and the thickness of the first semiconductor element 11, the number of insulative layers 1171 between the first upper winding 115a and the first lower winding 115b may preferably be between four and six. The dimension in the thickness direction z of the plurality of insulative layers 1171 between the first upper winding 115a and the first lower winding 115b (i.e., the distance along the thickness direction z between the first upper winding 115a and the first lower winding 115b) is not limited, but is between 9.6 and 14.4 μm, for example. This dimension example may correspond to a case in which four to six insulative layers 1171, each with a thickness of 2.4 μm, are stacked between the first upper winding 115a and the first lower winding 115b.

The wiring portion 118 is electrically connected between the pad 111 and the pad 112 and between the first upper winding 115a and the first lower winding 115b. The wiring portion 118 includes a plurality of through wirings 1181 and a lead-out wiring 1182. The through wirings 1181 each penetrate the one or more insulative layers 1171 in the thickness direction z. As understood from FIG. 9, the through wirings 1181 include one connecting the pad 111 to the lead-out wiring 1182, one connecting the lead-out wiring 1182 to the first lower winding 115b, and one connecting the pad 112 to the first upper winding 115a. The lead-out wiring 1182 is formed on the lowest insulative layer 1171. The lead-out wiring 1182 forms a part of the conduction path between the pad 111 and the first lower winding 115b.

The structure of the first semiconductor element 11 is not limited to the example described above. For example, the first semiconductor element 11 may further include other protective film (e.g., SiO₂ film) and passivation film (e.g., SiN film) stacked on the first obverse face 11a while exposing the pads 111 and 112, and a coil protective film that selectively covers the area right above the first upper winding 115a. Each of the first upper winding 115a and the first lower winding 115b is not limited to being provided in a planar spiral shape in one insulative layer 1171, but may be provided in a three-dimensional manner across the insulative layers 1171. However, in order to decrease the thickness of the first semiconductor element 11, it may be preferable for each of the first upper winding 115a and the first lower winding 115b to be provided in a planar spiral shape in one insulative layer 1171.

In the illustrated example, the second semiconductor element 12 includes a second obverse face 12a, a second reverse face 12b, a second seal ring 123, a second functional portion 125, a second semiconductor substrate 120, a laminated structure 127 and a wiring portion 128.

The second obverse face 12a and the second reverse face 12b are spaced apart from each other in the thickness direction z. The second obverse face 12a is the upper surface of the second semiconductor element 12 and the second reverse face 12b is the lower surface of the second semiconductor element 12. The second obverse face 12a is provided with a plurality of pads 121 and a plurality of pads 122. The composition of each of the pads 121 and 122 includes aluminum, for example. The second reverse face 12b faces the second lead 32.

The second seal ring 123 is formed along each of the four outer edges of the second semiconductor element 12 in plan view and surrounds the periphery of the circuit forming region. The second seal ring 123 includes a portion that protrudes from the second obverse face 12a in the thickness direction z. The second seal ring 123 is made of copper or aluminum, for example.

The second functional portion 125 is electrically connected to the pads 121 and 122. The second functional portion 125 includes internally a plurality of second upper windings 125a and a plurality of second lower windings 125b. More specifically, the second functional portion 125 includes a plurality of pairs comprising one second upper winding 125a and one second lower winding 125b. The second lower windings 125b are electrically connected to the respective pads 121. The second upper winding 125a are electrically connected to the respective pads 122. As an example, the pairs of the second upper winding 125a and the second lower winding 125b are arranged along the longitudinal direction (second direction y) of the second semiconductor element 12.

FIG. 8 shows one of the pairs of second upper winding 125a and the second lower winding 125b. In one pair of the second upper winding 125a and the second lower winding 125b, the second upper winding 125a is spaced apart from and faces the second lower winding 125b in the thickness direction z. In each pair of second upper windings 125a and the second lower windings 125b, the second upper winding 125a is magnetically coupled to the second lower winding 125b. The magnetic coupling is induced by the second semiconductor element 12. In other words, the second semiconductor element 12 inductively couples the second upper windings 125a and the second lower windings 125b to transmit electric signals in an insulated environment.

As the second semiconductor substrate 120, a silicon substrate, a silicon carbide substrate or the like can be utilized. Instead of the second semiconductor substrate 120, an insulating substrate such as a ceramic substrate or a resin substrate can be utilized for the second semiconductor element 12. The second seal ring 123 stands on the second semiconductor substrate 120. In the present embodiment, the potential of the second seal ring 123 is the same (or generally same) as the potential of the second semiconductor substrate 120.

The laminated structure 127 is formed on the second semiconductor substrate 120. The second seal ring 123 penetrates through the laminated structure 127 in the thickness direction z.

The laminated structure 127 includes a plurality of insulative layers 1271. The insulative layers 1271 are stacked on the top surface of the second semiconductor substrate 120. The insulative layers 1271 each include a stacked structure of a lower etching stopper film and an upper interlayer insulating film, except for the lowest insulative layer 1271 that is in contact with the top surface of the second semiconductor substrate 120. The lowest insulative layer 1271 may consist only of an interlayer insulating film. As the etching stopper film, silicon nitride film, silicon carbide film, or silicon carbonitride film can be utilized. As the interlayer insulating film, a silicon oxide film can be utilized. The dimension in the thickness direction z of each insulative layer 1271 is not limited, but is 2.4 μm, for example. The thickness of each insulative layer 1271 may be different from each other.

FIG. 9 shows an example of the internal structure of the second semiconductor element 12. In the illustrated second semiconductor element 12, the laminated structure 127 includes twelve insulative layers 1271. From the second semiconductor substrate 120, the second lower winding 125b is formed on the fourth insulative layer 1271 and the second upper winding 125a is formed on the eleventh insulative layer 1271, with six insulative layers 1271 sandwiched between the second upper winding 125a and the second lower winding 125b. In other words, the second upper winding 125a and the second lower winding 125b face each other, with one or more insulative layers 1271 interposed therebetween.

The number of insulative layers 1271 is not limited to the illustrated example and may be changed according to the magnitude of the voltage applied to each of the pad 121 and pad 122. The number of insulative layers 1271 may involve a trade-off relationship between the thickness and the dielectric strength in the second semiconductor element 12. The greater the number of insulative layers 1271 between the second upper winding 125a and the second lower winding 125b, the greater the dielectric strength in the second semiconductor element 12, but the thickness of the second semiconductor element 12 increases. On the other hand, the smaller the number of insulative layers 1271 between the second upper winding 125a and the second lower winding 125b, the less the dielectric strength in the second semiconductor element 12, but the thickness of the second semiconductor element 12 decreases.

In the present embodiment, in view of the relationship between the dielectric strength and the thickness of the second semiconductor element 12, the number of insulative layers 1271 between the second upper winding 125a and the second lower winding 125b may preferably be between four and six. The dimension in the thickness direction z of the plurality of insulative layers 1271 between the second upper winding 125a and the second lower winding 125b (i.e., the distance along the thickness direction z between the second upper winding 125a and the second lower winding 125b) is not limited, but is between 9.6 and 14.4 μm, for example. This dimension example may correspond to a case in which four to six insulative layers 1271, each with a thickness of 2.4 μm, are stacked between the second upper winding 125a and the second lower winding 125b.

The wiring portion 128 is electrically connected between the pads 121 and the pads 122 and between the second upper winding 125a and the second lower winding 125b. The wiring portion 128 includes a plurality of through wirings 1281 and a lead-out wiring 1282. The through wirings 1281 each penetrate the one or more insulative layers 1271 in the thickness direction z. As understood from FIG. 9, the through wirings 1281 include one connecting the pad 121 to the lead-out wiring 1282, one connecting the lead-out wiring 1282 to the second lower winding 125b, and one connecting the pad 122 to the second upper winding 125a. The lead-out wiring 1282 is formed on the lowest insulative layer 1271. The lead-out wiring 1282 forms a part of the conduction path between the pad 121 and the second lower winding 125b.

The structure of the second semiconductor element 12 is not limited to the example described above. For example, the second semiconductor element 12 may further include other protective film (e.g., SiO₂ film) and passivation film (e.g., SiN film) stacked on the second obverse face 12a while exposing the pads 121 and 122, and a coil protective film that selectively covers the area right above the second upper winding 125a. Each of the second upper winding 125a and the second lower winding 125b is not limited to being provided in a planar spiral shape in one insulative layer 1271, but may be provided in a three-dimensional manner across the insulative layers 1271. However, in order to decrease the thickness of the second semiconductor element 12, it may be preferable for each of the second upper winding 125a and the second lower winding 125b to be provided in a planar spiral shape on one insulative layer 1271.

The fourth semiconductor element 14 needs a higher supply voltage than the third semiconductor element 13. Thus, a potential difference arises between the third semiconductor element 13 and the fourth semiconductor element 14. In other words, a first circuit including the third semiconductor element 13 and a second circuit including the fourth semiconductor element 14 have relatively different potentials. In addition to the third semiconductor element 13, the components of the first circuit include the first lead 31, the third leads 33, the second wires 42, the fourth wires 44, the sixth wire 46, and a part (such as each pad 111 and each first lower winding 115b) of the first semiconductor element 11. In addition to the fourth semiconductor element 14, the components of the second circuit include the second lead 32, the fourth leads 34, the third wires 43, the fifth wires 45, the seventh wire 47, and a part (such as each pad 121 and each second lower winding 125b) of the second semiconductor element 12. In the semiconductor device A1, the potential of the second circuit is higher than that of the first circuit. In an inverter for an electric vehicle or a hybrid vehicle, the voltage applied to the ground of the third semiconductor element 13 may be about 0 V, while the voltage applied to the ground of the fourth semiconductor element 14 may transiently be 600 V or higher. Further, depending on the specifications of the inverter, the voltage applied to the ground of the fourth semiconductor element 14 may be 3750 V or more.

The semiconductor device A1 includes a third circuit in addition to the first and the second circuits. Specifically, the semiconductor device A1 includes a third circuit with an intermediate potential between the potentials of the first circuit and the second circuit, resulting from insulation of the first semiconductor element 11 and the second semiconductor element 12 (two insulating elements). In the present embodiment, the third circuit includes a part of the first semiconductor element 11 (such as each first upper winding 115a and each pad 112), a part of the second semiconductor element 12 (such as each second upper winding 125a and each pad 122), the first wires 41 and the bump-stacked bodies 2. In the configuration where the potential of the second circuit is higher than the potential of the first circuit, the potential of the third circuit is higher than the potential of the first circuit and lower than the potential of the second circuit. In the present embodiment, the voltage difference between the first circuit and the second circuit is equally shared by the first semiconductor element 11 and the second semiconductor element 12. Hence, the potential of the third circuit is half of the potential difference between the first circuit and the second circuit. The potential of the third circuit is not limited to half of the potential difference between the first circuit and the second circuit, but may be biased toward either the potential of the first circuit or the second circuit.

The bump-stacked bodies 2 are disposed on the respective pads 122 of the second semiconductor element 12. Each of the bump-stacked bodies 2 is formed from a plurality of bumps 21 disposed in a stacked arrangement along the z direction. Each bump 21 mainly contains a metallic material. The metallic material includes gold (Au), copper or aluminum. Hence, via the bump-stacked bodies 2, the first semiconductor element 11 is electrically connected to the second semiconductor element 12. The number of bumps 21 in the bump-stacked body 2 may be changed according to the thickness of the first semiconductor element 11 and the second semiconductor element 12.

Each bump 21 may correspond to a ball portion of the first bonding in ball bonding. FIG. 8 shows one of the bump-stacked bodies 2. In the illustrated example, the bump-stacked body 2 comprises three bumps 21. The three bumps 21 include a first bump 21a, a second bump 21b, and a third bump 21c stacked in sequence. The third bump 21c is in contact with the pad 122. The number of bumps 21 in each bump-stacked body 2 may mutually vary.

The conductive support member 3 provides a conductive path between a wiring board on which the semiconductor device A1 is mounted and the first semiconductor element 11, the second semiconductor element 12, the third semiconductor element 13, or the fourth semiconductor element 14. For example, the conductive support member 3 is formed from the same lead frame, as will be described in detail later. The lead frame is made of copper or a copper alloy, for example, but may be made of other metallic materials.

The first semiconductor element 11 and the third semiconductor element 13 is mounted on and electrically connected to the first lead 31. In the illustrated example, the first lead 31 includes a first island portion 311 and two first terminal portions 312.

In the illustrated example, the first island portion 311 is a rectangular part of the first lead 31 in plan view. The first island portion 311 is covered by the sealing resin 5. The first island portion 311 is at the same (or generally same) potential as the first semiconductor substrate 110 of the first semiconductor element 11. The thickness of the first island portion 311 is between 100 and 300 μm, for example. Unlike the illustrated example, the first island portion 311 may be formed with a through hole penetrating in the thickness direction z. The through hole may be formed between the first semiconductor element 11 and the third semiconductor element 13, for example.

The first island portion 311 includes a first mount face 311a facing one side (upside) of the thickness direction z. On the first mount face 311a, the first semiconductor element 11 is bonded via the first conductive bonding material 119 and the third semiconductor element 13 is bonded via the third conductive bonding material 139. The first conductive bonding material 119 and the third conductive bonding material 139 are solder, metal paste or sintered metal, for example.

The two first terminal portions 312 are spaced apart from each other in the second direction y. The two first terminal portions 312 include one connected to the first island portion 311 and one not connected to the first island portion 311. The two first terminal portions 312 each include a covered portion 312a covered by the sealing resin 5 and an exposed portion 312b exposed from the sealing resin 5. The covered portion 312a of one first terminal portion 312 is connected to the first island portion 311, and the covered portion 312a of the other first terminal portion 312 is not connected to the first island portion 311.

The exposed portions 312b of the two first terminal portions 312 are connected to the respective covered portions 312a. In plan view, each exposed portion 312b extends along the first direction x. In the illustrated example, the exposed portion 312b is bent in a gull wing shape as viewed in the second direction y. The surface of each exposed portion 312b may be plated with tin (Sn). Each covered portion 312a includes an outer portion 312a1 and an inclined portion 312a2. The outer portion 312a1 is connected to the exposed portion 312b and extends in the first direction x. The inclined portion 312a2 is connected to the first island portion 311 and inclines to one side of the second direction y as it proceeds in one side of the first direction x.

The second semiconductor element 12 and the fourth semiconductor element 14 is mounted on and electrically connected to the second lead 32. The second lead 32 is separated from the first lead 31 in the first direction x. In the illustrated example, the second lead 32 includes a second island portion 321 and two second terminal portions 322.

In the illustrated example, the second island portion 321 is a rectangular part of the second lead 32 in plan view. The second island portion 321 is covered by the sealing resin 5. The second island portion 321 is at the same (or generally same) potential as the second semiconductor substrate 120 of the second semiconductor element 12. The thickness of the second island portion 321 is between 100 and 300 μm, for example. The thickness of the second island portion 321 may be the same as that of the first island portion 311. Unlike the illustrated example, the second island portion 321 may have a through hole penetrating in the thickness direction z. The through hole may be formed between the second semiconductor element 12 and the fourth semiconductor element 14, for example.

The second island portion 321 includes a second mount face 321a facing one side (upside) in the thickness direction z. On the second mount face 321a, the second semiconductor element 12 is bonded via the second conductive bonding material 129 and the fourth semiconductor element 14 is bonded via the fourth conductive bonding material 149. The second conductive bonding material 129 and the fourth conductive bonding material 149 are solder or metal paste or sintered metal, for example. In the illustrated example, the second island portion 321 overlaps with the first island portion 311 as viewed in the first direction x.

The two second terminal portions 322 are spaced apart from each other in the second direction y. The two second terminal portions 322 each include a covered portion 322a covered by the sealing resin 5 and an exposed portion 322b exposed from the sealing resin 5. The covered portion 322a of one second terminal portion 322 is connected to the second island portion 321, and the covered portion 322a of the other second terminal portion 322 is not connected to the second island portion 321.

The exposed portions 322b of the two second terminal portions 322 are connected to the respective covered portions 322a. In plan view, each exposed portion 322b extends along the first direction x. In the illustrated example, the exposed portion 322b is bent in a gull wing shape as viewed in the second direction y. The surface of each exposed portion 322b may be plated with tin. Each covered portion 322a includes an outer portion 322a1 and an inclined portion 322a2. The outer portion 322a1 is connected to the exposed portion 322b and extends in the first direction x. The inclined portion 322a2 is connected to the second island portion 321 and inclines to one side of the second direction y as it proceeds in one side of the first direction x.

In the illustrated example, the third leads 33 are located opposite the second island portion 321 of the second lead 32 with respect to the first island portion 311 of the first lead 31 in the first direction x. The third leads 33 are arranged along the second direction y. The third leads 33 each includes a plurality (four in the illustrated example) of intermediate leads 33A and two side leads 33B. The intermediate leads 33A are located between the two side leads 33B in the second direction y. In the second direction y, each side lead 33B is located between one of the two first terminal portions 312 of the first lead 31 and the intermediate lead 33A closest to the first terminal portion 312.

In the illustrated example, the third leads 33 (intermediate leads 33A and two side leads 33B) each include a covered portion 331 and an exposed portion 332. The covered portions 331 are covered by the sealing resin 5. In the illustrated example, the dimension in the first direction x of the covered portion 331 of each outer lead 33B is greater than the dimension in the first direction x of the covered portion 331 of each intermediate lead 33A. In the illustrated example, the exposed portions 332 are each connected to the covered portion 331 and exposed from the sealing resin 5. In plan view, the exposed portion 332 extends in the first direction x. As viewed in the second direction y, each exposed portion 332 is bent in a gull wing shape. The shape of each exposed portion 332 is equal to the shape of each exposed portion 312b of the first lead 31. The surface of the exposed portion 332 may be plated with tin.

The shape, arrangement and number of the third leads 33 are not limited to the illustrated example. For example, the number of the third leads 33 may be six, a part of which may be arranged outside of the first terminal portions 312 of the two first leads 31.

In the illustrated example, the fourth leads 34 are located opposite the third leads 33 with respect to the first island portion 311 of the first lead 31 in the first direction x. The fourth leads 34 are arranged along the second direction y. The fourth leads 34 each include a plurality (four in the illustrated example) of intermediate leads 34A and two side leads 34B. The intermediate leads 34A are located between the two side leads 34B in the second direction y. In the second direction y, each side lead 34B is located between one of the two second terminal portions 322 of the second lead 32 and the intermediate lead 34A closest to the second terminal portion 322.

In the illustrated example, the fourth leads 34 (intermediate leads 34A and two outer leads 34B) each include a covered portion 341 and an exposed portion 342. The covered portions 341 are covered by the sealing resin 5. In the illustrated example, the dimension in the first direction x of the covered portion 341 of each outer lead 34B is greater than the dimension in the first direction x of the covered portion 341 of each intermediate lead 34A. In the illustrated example, the exposed portions 342 are each connected to the covered portion 341 and exposed from the sealing resin 5. In plan view, the exposed portion 342 extends in the first direction x. As viewed in the second direction y, each exposed portion 342 is bent in a gull wing shape. The shape of each exposed portion 342 is equal to the shape of each exposed portion 322b of the second lead 32. The surface of the exposed portion 342 may be plated with tin.

The shape, arrangement and number of the fourth leads 34 are not limited to the illustrated examples. For example, the number of the fourth leads 34 may be six, a part of which may be arranged outside of the two second terminal portions 322 of the second lead 32.

The connection members 4 are each electrically connected between two sites that are spaced apart from each other. The first wires 41 are bonded to the respective pads 112 of the first semiconductor element 11 and the respective bump-stacked bodies 2. The second wires 42 are bonded to the respective pads 111 of the first semiconductor element 11 and the respective pads 131 of the third semiconductor element 13. The third wires 43 are bonded to the respective pads 121 of the second semiconductor element 12 and the respective pads 141 of the fourth semiconductor element 14. The fourth wires 44 are bonded to the respective pads 131 of the third semiconductor element 13 and the respective covered portions 331 of the third lead 33. The fifth wires 45 are bonded to the respective pads 141 of the fourth semiconductor element 14 and the respective covered portions 341 of the fourth lead 34. The sixth wire 46 is bonded to one of the pads 131 of the third semiconductor element 13 and one of the covered portions 312a of the first terminal portions 312. The seventh wire 47 is bonded to one of the pads 141 of the fourth semiconductor element 14 and one of the covered portions 341 of the second terminal portions 322a.

The first wires 41, the second wires 42, the third wires 43, the fourth wires 44, the fifth wires 45, the sixth wire 46 and the seventh wire 47 each contain a metallic material including gold, copper, or aluminum, for example. Alternatively, the connection members 4 may be bonding ribbons or plate-like metal members instead of the first wires 41, the second wires 42, the third wires 43, the fourth wires 44, the fifth wires 45, the sixth wire 46 and the seventh wire 47.

Each first wire 41 electrically connects the first semiconductor element 11 and the second semiconductor element 12. The first wires 41 are arranged along the second direction y. In plan view, the first wires 41 each bridge the first island portion 311 of the first lead 31 and the second island portion 321 of the second lead 32.

FIG. 8 shows one of the first wires 41. As shown in FIG. 8, the first wire 41 includes a bonding portion 411, a bonding portion 412, and a loop portion 413. The bonding portion 411 is the opposite end of the bonding portion 412. As an example, the bonding portion 411 may correspond to a first bonding and the bonding portion 412 to a second bonding. The bonding portion 411 includes a ball portion of the first bonding. The loop portion 413 is connected to the bonding portion 411 and the bonding portion 412. In the present embodiment, the bump-stacked body 2 is located between the bonding portion 412 and the pad 122. The bonding portion 411 is bonded to one of the pads 112 of the first semiconductor element 11 and extends in the thickness direction z. The bonding portion 412 is bonded to one of the bump-stacked bodies 2 on the pads 122. The loop portion 413 extends from the bonding portion 411 to the bonding portion 412 while curving.

In the present disclosure, the bonding portion 411 and the bonding portion 412 may correspond to a “first end” and a “second end”, respectively. The bonding portion 411 is located differently from the bonding portion 412 in the thickness direction z. Specifically, the distance between the bonding portion 411 and the first island portion 311 along the thickness direction z is smaller than the distance between the bonding portion 412 and the second island portion 321 along the thickness direction z.

Each second wire 42 electrically connects the first semiconductor element 11 and the third semiconductor element 13. The second wires 42 are arranged along the second direction y. In plan view, the second wires 42 bridge the respective pads 111 of the first semiconductor element 11 and the respective pads 131 of the third semiconductor element 13.

FIG. 8 shows one of the second wires 42. As shown in FIG. 8, the second wire 42 includes a bonding portion 421, a bonding portion 422, and a loop portion 423. The bonding portion 421 is the opposite end of the bonding portion 422. As an example, the bonding portion 421 may correspond to a first bonding, and the bonding portion 422 to a second bonding. The bonding portion 421 includes a ball portion of the first bonding. The loop portion 423 is connected to the bonding portion 421 and the bonding portion 422. The bonding portion 421 is bonded to one of the pads 111 of the first semiconductor element 11 and extends in the thickness direction z. The bonding portion 422 is bonded to one of the pads 131. The loop portion 423 extends from the bonding portion 421 to the bonding portion 422 while curving.

In the present disclosure, the bonding portion 421 and the bonding portion 422 may correspond to a “third end” and a “fourth end”, respectively.

As shown in FIG. 8, an internal angle α at the bonding portion 412 of the first wire 41 may be greater than an internal angle β at the bonding portion 422 of the second wire 42. The internal angle α corresponds to the internal angle between the bonding portion 412 and the horizontal plane (i.e., the second obverse face 12a or the surface of the pad 111). The internal angle β corresponds to the internal angle between the bonding portion 422 and the horizontal surface (i.e., the third obverse face 13a or the surface of the pad 121). The values of the internal angle α and the internal angle β are not particularly limited.

Each third wire 43 electrically connects the second semiconductor element 12 and the fourth semiconductor element 14. The third wires 43 are arranged along the second direction y. In plan view, the third wires 43 bridge the respective pads 121 of the second semiconductor element 12 and the respective pads 141 of the fourth semiconductor element 14.

FIG. 8 shows one of the third wires 43. As shown in FIG. 8, the third wire 43 includes a bonding portion 431, a bonding portion 432, and a loop portion 433. The bonding portion 431 is the opposite end of the bonding portion 432. The bonding portion 431 is bonded to one of the pads 121 and extends in the thickness direction z. The bonding portion 432 is bonded to one of the pads 141. The loop portion 433 is connected to the bonding portion 431 and the bonding portion 432. The loop portion 433 extends from the bonding portion 431 to the bonding portion 432 while curving.

In the present disclosure, the bonding portion 431 and the bonding portion 432 correspond to a “fifth end” and a “sixth end”, respectively. As shown in FIG. 8, the internal angle α at the bonding portion 412 of the first wire 41 is greater than an internal angle γ at the bonding portion 432 of the third wire 43. The internal angle γ may be equal to the internal angle β. The internal angle γ corresponds to the internal angle between the bonding portion 432 and the horizontal surface (i.e., the fourth obverse face 14a or the surface of the pad 141). The value of the internal angle γ is not particularly limited.

The fourth wires 44 electrically connect the third semiconductor element 13 and the respective third leads 33. In other words, at least one of the third leads 33 is electrically connected to the third semiconductor element 13 via the fourth wire 44.

The fifth wires 45 electrically connect the fourth semiconductor element 14 and the respective fourth leads 34. In other words, at least one of the fourth leads 34 is electrically connected to the fourth semiconductor element 14 via the fifth wire 45.

The sixth wire 46 electrically connects the third semiconductor element 13 and one of the first leads 31. In the present embodiment, one of the two first terminal portions 312 is electrically connected to the ground of the third semiconductor element 13 via the sixth wire 46.

The seventh wire 47 electrically connects the fourth semiconductor element 14 and one of the second leads 32. In the present embodiment, one of the two second terminal portions 322 is electrically connected to the ground of the fourth semiconductor element 14 via the seventh wire 47.

The sealing resin 5 covers, in the illustrated example, the first semiconductor element 11, the second semiconductor element 12, the third semiconductor element 13, the fourth semiconductor element 14, a part of the conductive support member 3 (a part of each of the first lead 31, the second lead 32, the third lead 33, and the fourth lead 34), and the connection members 4. The sealing resin 5 has electrical insulation properties. The sealing resin 5 insulates the components of the first circuit (e.g., the first lead 31) and the components of the second circuit (e.g., the second lead 32) from each other. The component material of the sealing resin 5 may include a black epoxy resin. In the illustrated example, the sealing resin 5 is rectangular in plan view.

In the illustrated example, the sealing resin 5 includes a top face 51, a bottom face 52, a pair of first side faces 53, and a pair of second side faces 54.

The top face 51 and the bottom face 52 are spaced apart from each other in the thickness direction z. The top face 51 and the bottom face 52 face opposite each other in the thickness direction z. The top face 51 and the bottom face 52 are flat (or generally flat).

The pair of first side faces 53 are connected to the top face 51 and the bottom face 52, and are located apart from each other in the first direction x. In the illustrated example, the exposed portions 312b of the two first terminal portions 312 (first leads 31) and the exposed portions 332 of the third leads 33 are exposed from the first side face 53 located on one side of the first direction x among the pair of first side faces 53. The exposed portions 322b of the two second terminal portions 322 (second leads 32) and the exposed portions 342 of the fourth leads 34 are exposed from the first side face 53 located on the other side of the first direction x among the pair of first side faces 53.

In the illustrated example, each of the pair of first side faces 53 includes a first upper portion 531, a first lower portion 532, and a first intermediate portion 533. The first upper portion 531 is connected to the top face 51 on one side of the thickness direction z and to the first intermediate portion 533 on the other side of the thickness direction z. The first upper portion 531 is inclined with respect to the top face 51. The first lower portion 532 is connected to the bottom face 52 on one side of the thickness direction z and to the first intermediate portion 533 on the other side of the thickness direction z. The first lower portion 532 is inclined with respect to the bottom face 52. The first intermediate portion 533 is connected to the first upper portion 531 on one side of the thickness direction z and to the first lower portion 532 on the other side of the thickness direction z. The in-plane directions of the first intermediate portion 533 are the thickness direction z and the second direction y. In plan view, the first intermediate portion 533 is located outside of the top face 51 and the bottom face 52. From the first intermediate portions 533 of the first side faces 53 are each exposed the exposed portions 312b of the two first terminal portions 312 (first leads 31), the exposed portions 322b of the two second terminal portions 322 (second leads 32), the exposed portions 332 of the third leads 33 and the exposed portions 342 of the fourth leads 34.

In the illustrated example, the pair of second side faces 54 are connected to the top face 51 and the bottom face 52, and are located apart from each other in the second direction y. In the illustrated example, the first lead 31, the second lead 32, the third leads 33 and the fourth leads 34 are spaced apart from the pair of second side faces 54.

In the illustrated example, each of the pair of second side faces 54 includes a second upper portion 541, a second lower portion 542, and a second intermediate portion 543. The second upper portion 541 is connected to the top face 51 on one side of the thickness direction z and to the second intermediate portion 543 on the other side of the thickness direction z. The second upper portion 541 is inclined with respect to the top face 51. The second lower portion 542 is connected to the bottom face 52 on one side of the thickness direction z and to the second intermediate portion 543 on the other side of the thickness direction z. The second lower portion 542 is inclined with respect to the bottom face 52. The second intermediate portion 543 is connected to the second upper portion 541 on one side of the thickness direction z and to the second lower portion 542 on the other side of the thickness direction z. The in-plane directions of the second intermediate portion 543 are the thickness direction z and the second direction y. In plan view, the second intermediate portion 543 is located outside of the top face 51 and the bottom face 52.

Typically, a motor driver circuit in an inverter includes a half-bridge circuit including a low-side (low potential side) switching element and a high-side (high potential side) switching element. In the following description, these switching elements are assumed to be MOSFETs. For the low-side switching element, the source of the switching element and its gate driver are referenced to ground. For the high-side switching element, the source of the switching element and its gate driver are referenced to the output node of the half-bridge circuit. The driving of the high-side and low-side switching elements causes the potential at the output node to fluctuate. This fluctuation leads to a change in the reference potential of the gate driver for the high-side switching element. When the high-side switching element is on, the reference potential of the gate driver for the high-side switching element is equivalent to the voltage applied to the drain of the high-side switching element (e.g., 600 V or higher). In the semiconductor device A1, the ground of the third semiconductor element 13 and the ground of the fourth semiconductor element 14 are separated. Therefore, when the semiconductor device A1 is used as a gate driver to drive the high-side switching element, a voltage equivalent to the voltage applied to the drain of the high-side switching element is transiently applied to the ground of the fourth semiconductor element 14.

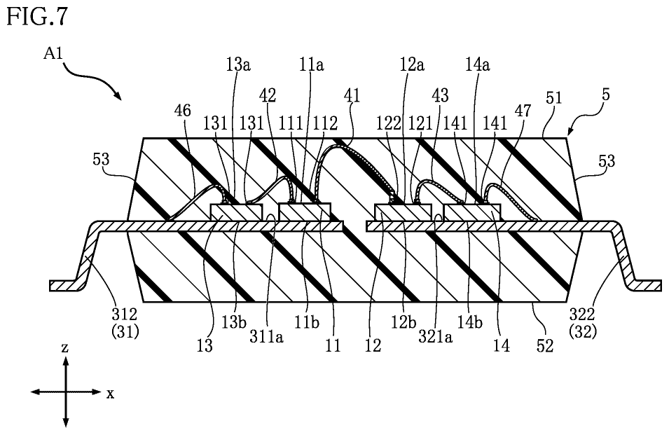

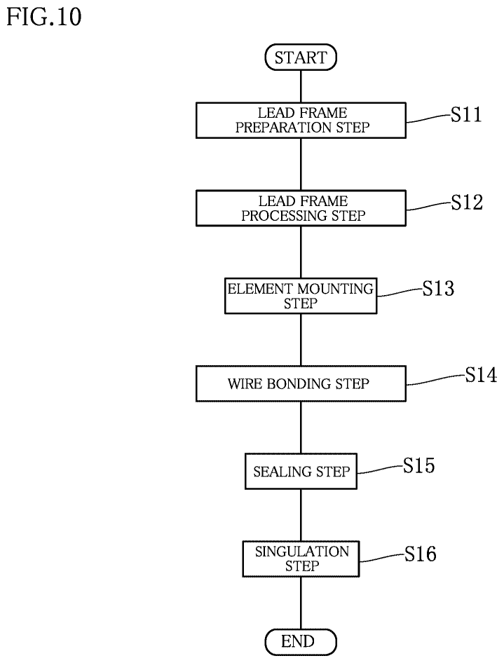

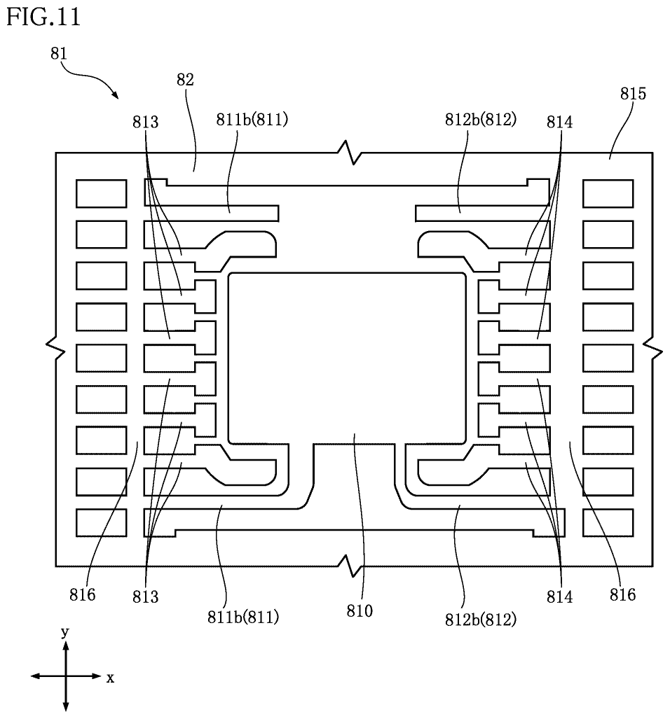

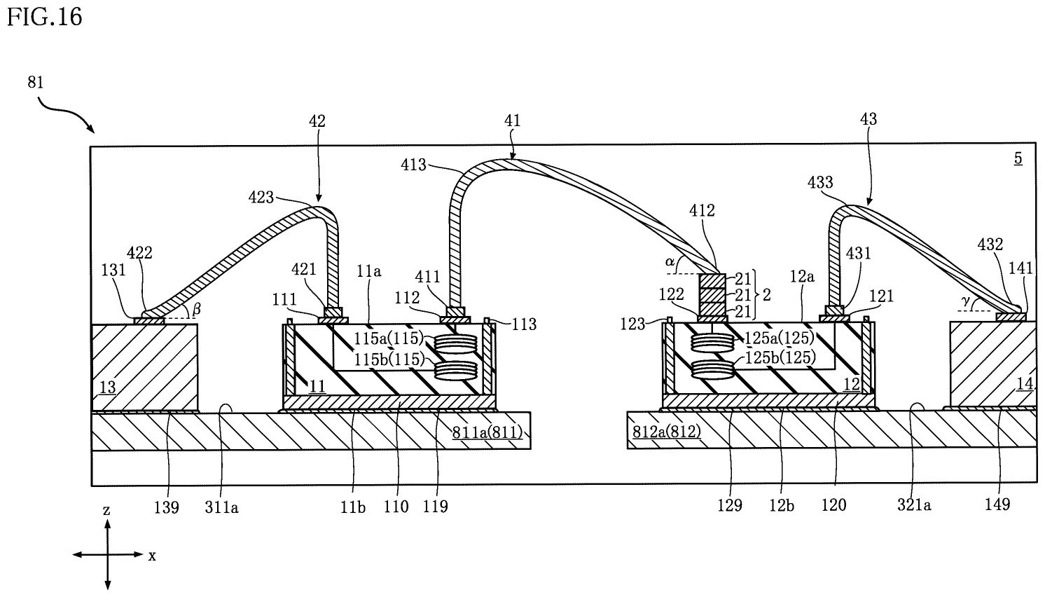

Next, an example of a method for manufacturing the semiconductor device A1 will be described with reference to FIGS. 10 to 17. FIG. 10 is a flowchart showing an example of the method for manufacturing the semiconductor device A1. FIGS. 11 to 15 and 17 are plan views each showing one step of the method for manufacturing the semiconductor device A1. FIG. 16 is a sectional view showing one step of the method for manufacturing the semiconductor device A1. The cross-section in FIG. 16 has the same cross-sectional position as that in FIG. 7.

As shown in FIG. 10, the method for manufacturing the semiconductor device A1 includes a lead frame preparation step S11, a lead frame processing step S12, an element mounting step S13, a wire bonding step S14, a sealing step S15, and a singulation step S16.

First, in the lead frame preparation step S11, a lead frame 81 shown in FIG. 11 is prepared. As shown in FIG. 11, the lead frame 81 includes a flat plate portion 810, a plurality of support leads 811b, 812b, a plurality of leads 813, 814, an outer frame 815, and a dam bar 816. The lead frame 81 is formed, for example, by punching out a copper sheet with a rectangular shape in plan view. The support leads 811b, 812b are each connected to the flat plate portion 810. The support leads 811b, 812b and the leads 813, 814 are connected via the outer frame 815 and the dam bar 816. Among the lead frame 81, the outer frame 815 and the dam bar 816 will not remain as parts of the semiconductor device A1.

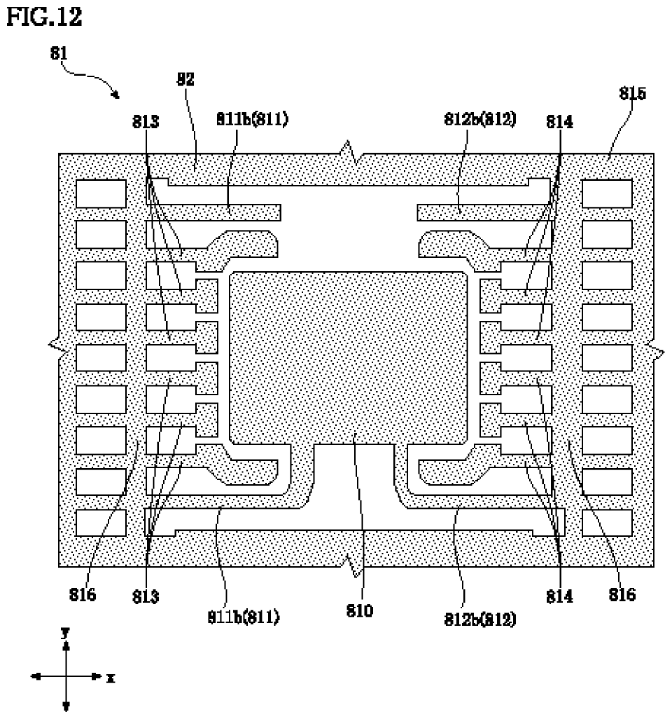

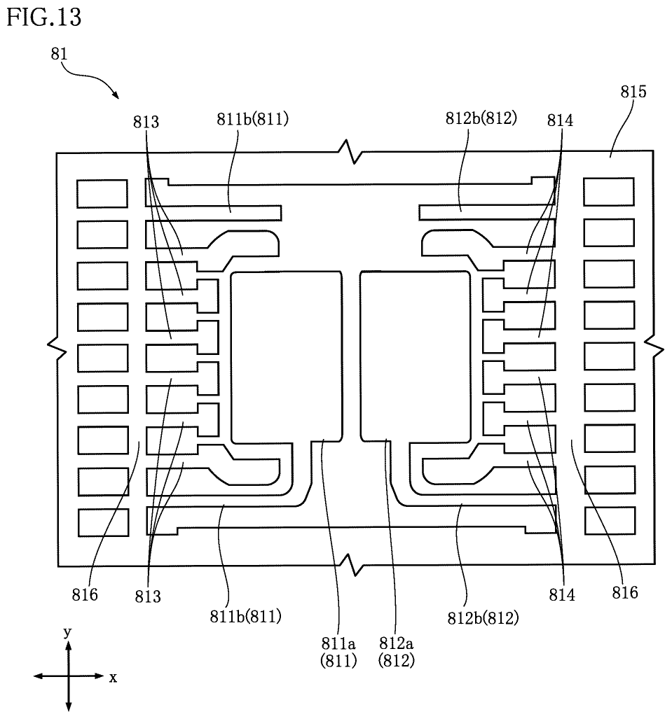

Next, in the lead frame processing step S12, the flat plate portion 810 of the lead frame 81 is divided. At first, the lead frame 81 is coated with a resist 82. In FIG. 12, the resist 82 is drawn as dots. Then, the lead frame 81 with the resist 82 is etched. As a result, a part of the lead frame 81 without the resist 82 is removed, and the flat plate portion 810 is divided into a first island 811a and a second island 812a. Then, the resist 82 is removed so as to form the lead frame 81 with the first island 811a and the second island 812a, as shown in FIG. 13. In the lead frame 81, the support leads 811b are connected to the first island 811a, and the support leads 812b are connected to the second island 812a. In this manner, a first lead 811 including the first island 811a and the support leads 811b and a second lead 812 including a second island 812a and the support leads 812b are formed.

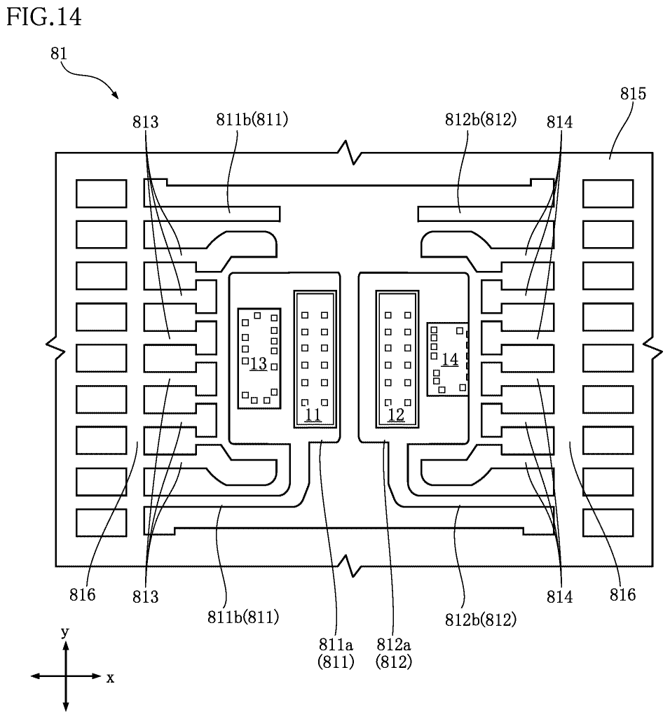

Next, in the element mounting step S13, the first semiconductor element 11, the second semiconductor element 12, the third semiconductor element 13, and the fourth semiconductor element 14 are mounted on the lead frame 81, as shown in FIG. 14. Specifically, the first semiconductor element 11 and the third semiconductor element 13 are each bonded to the first island 811a by a conductive bonding material not shown, and the second semiconductor element 12 and the fourth semiconductor element 14 are bonded to the second island 812a by a conductive bonding material not shown.

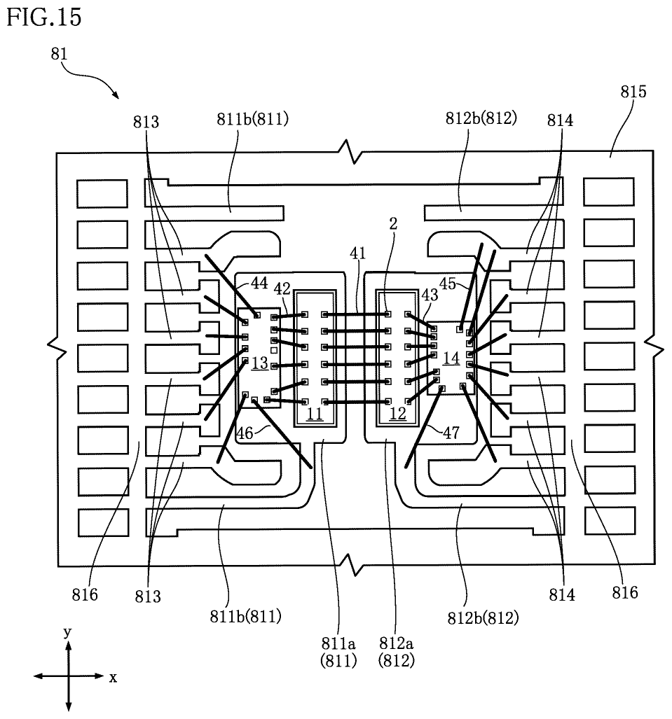

Next, in the wire bonding step S14, the bump-stacked bodies 2 and the connection members 4 are formed, as shown in FIGS. 15 and 16.

Each of the first wires 41, the second wires 42, the third wires 43, the fourth wires 44, the fifth wires 45, the sixth wire 46 and the seventh wire 47 may be formed, for example, by ball bonding. Regarding each first wire 41, the first bond is made at one of the pads 112 to form the bonding portion 411, and then the second bond is made at one of the bump-stacked bodies 2 to form the bonding portion 412. Regarding each second wire 42, the first bond is made at one of the pads 111 to form the bonding portion 421, and then the second bond is made at one of the pads 131 to form the bonding portion 422. Regarding each three wire 43, the first bond is made at one of the pads 121 to form the bonding portion 431, and then the second bond is made at one of the pads 141 to form the bonding portion 432. Alternatively, of the first wires 41, the second wires 42, and the third wires 43 can be formed by other techniques such as wedge bonding. In this case, instead of the bonding portion 411, the pad 112 is bonded to a bonding portion with a shape roughly the same as the bonding portion 412, for example.

Each bump-stacked body 2 is formed by stacking bumps 21. Each bump 21 can be formed by terminating ball bonding with only first bonding (i.e., cutting the ball portion of the first bonding). More specifically, each bump-stacked body 2 is formed by repeating the procedure of forming one bump 21 by one ball bonding and another bump 21 on top of it. The first wires 41 are bonded on the respective bump-stacked bodies 2. A known wire bonder can be used to form each wire 41-47. The wires 41-47 may be formed in any sequence.

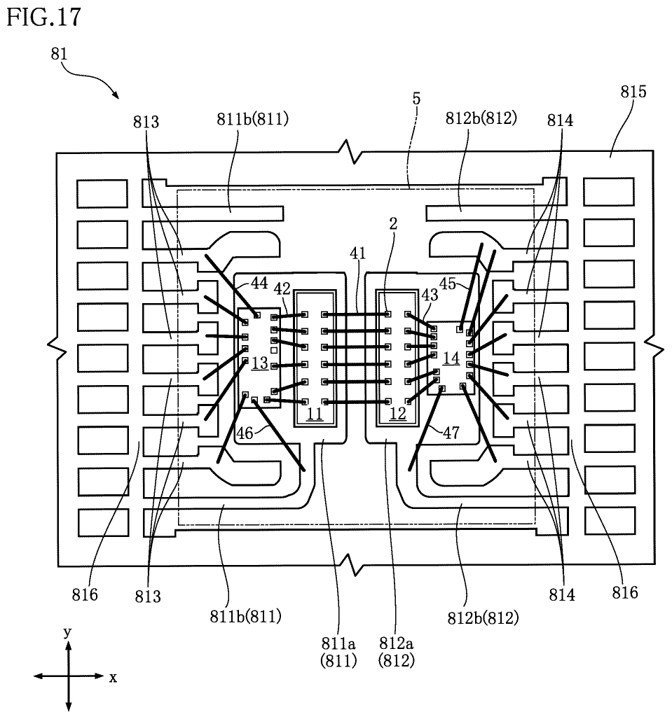

Next, in the sealing step S15, the sealing resin 5 is formed as shown in FIG. 17. In FIG. 17, the sealing resin 5 is shown as imaginary lines (double-dotted lines). The sealing resin 5 is formed by transfer molding. The sealing resin 5 is made of epoxy resin, for example.

Then, the singulation step S16 is performed, in which the lead frame 81 is diced and separated into individual pieces. As a result, the first lead 811, the second lead 812, and the leads 813, 814, which were connected to each other by the outer frame 815 and the dam bar 816, are separated. The first lead 31 is formed from the separated first lead 811. The first island 811a becomes the first island portion 311, and the support leads 811b become the respective first terminal portions 312. The second lead 32 is formed from the separated second lead 812. The second island 812a becomes the second island portion 321, and the support leads 812b become the respective second terminal portions 322. The third leads 33 are formed from the separated leads 813, and the fourth leads 34 are formed from the separated leads 814. The third leads 33 (leads 813) and the fourth leads 34 (leads 814) may be bent during the punching step in the lead frame preparation step S11 or the singulation step S16.

Through the steps shown above, the semiconductor device A1 is manufactured. The following options may be applied in the method for manufacturing the semiconductor device A1. For example, the first island 811a and the second island 812a may be formed during the punching step in the lead frame preparation step S11 without the lead frame processing step S12. As another option, a rectangular copper plate may be coated with the resist 82 and etched in the lead frame preparation step S11 rather than the lead frame processing step S12, thereby forming the first lead 811 (first island 811a and support leads 811b), the second lead 812 (second island 812a and support leads 812b), the leads 813, 814, the outer frame 815, and the dam bar 816 in a single batch.

Operative effects of the semiconductor device A1 are as follows.

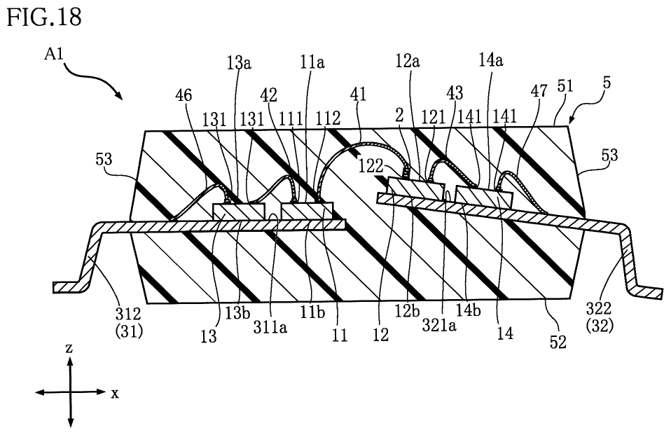

The semiconductor device A1 is less prone to dielectric breakdown even when failures such as lead (e.g., the second lead 32) deformation occur. An example of the lead deformation is shown in FIG. 18. FIG. 18 is merely an example of a deformation of a semiconductor device and does not limit the scope of the invention. In the illustrated example, the second lead 32 is deformed to bend in the thickness direction z. The first wire 41 may approach the surface of the second semiconductor element 12, particularly the second seal ring 123 protruding from the pad 122. In conventional semiconductor devices that does not assume the position of the end of the wire, the first wire 41 may approach the first semiconductor element 11 or the second semiconductor element 12 to such an extent that dielectric breakdown may occur. On the other hand, the semiconductor device A1 includes the first wire 41 with a margin to avoid the proximity of the first wire 41 to the first semiconductor element 11 or the second semiconductor element 12. The margin of the first wire 41 may be achieved by the different positions of the bonding portion 411 and the bonding portion 412 in the thickness direction z. In the present embodiment, the bump-stacked body 2 is provided between the second semiconductor element 12 and the bonding portion 412, so that the bonding portion 411 of the first wire 41 is located differently from the bonding portion 412 of the first wire 41 in the thickness direction z. Thus, the semiconductor device A1 has an advantage of reducing the occurrence of dielectric breakdown.

In the semiconductor device A1, the bump-stacked bodies 2 are formed on the respective pads 122. The bump-stacked body 2 increases the distance in the thickness direction z between the bonding portion 412 and the second seal ring 123. Such a configuration may further reduce the occurrence of dielectric breakdown between the first wire 41 and the second seal ring 123.

In a conventional configuration in which the third semiconductor element 13 and the fourth semiconductor element 14 are electrically insulated by a single semiconductor element (insulating element), a voltage difference between two circuits is generated within a single insulating element. In contrast, in the semiconductor device A1, the voltage difference between the first circuit and the second circuit is shared by two insulating elements (the first semiconductor element 11 and the second semiconductor element 12). Hence, the voltage difference in each of the first semiconductor element 11 and the second semiconductor element 12 may be reduced. Thus, the semiconductor device A1 has an advantage of improving the dielectric strength between the first lead 31 (first island portion 311) and the first semiconductor element 11, compared to a configuration in which a single insulating element is used for electrical isolation. Similarly, the dielectric strength between the second lead 32 (second island portion 321) and the second semiconductor element 12 may be improved.

In the semiconductor device A1, the number of insulative layers 1171 between the first upper winding 115a and the first lower winding 115b may be reduced while reducing the voltage difference in the first semiconductor element 11. This reduces the thickness of the first semiconductor element 11, thereby thinning the semiconductor device A1. The same may be applied to the second semiconductor element 12. In other words, the semiconductor device A1 may be thinned while maintaining the same dielectric strength between the first semiconductor element 11 and the second semiconductor element 12, compared to a configuration in which a single insulating element is used for electrical isolation. Even if the thickness of the semiconductor device A1 is limited by product specifications or the like, within that limited thickness, the dielectric strength of the semiconductor device A1 may be improved compared to a configuration in which a single insulating element is used for electrical isolation. This is because the insulative layers 1171 between the first upper winding 115a and the first lower winding 115b of the first semiconductor element 11 and the insulative layers 1271 between the second upper winding 125a and the second lower winding 125b of the second semiconductor element 12 insulate the first and the second circuits.

In the semiconductor device A1, the internal angle α between the bonding portion 412 of the first wire 41 and the horizontal plane (or the pad 111) is greater than the internal angle β between the bonding portion 422 of the second wire 42 and the horizontal plane (or the pad 121). Such a configuration may provide a sufficient distance between the first wire 41 and the second seal ring 123, even if the semiconductor device A1 is deformed as shown in FIG. 18. In other words, the first wire 41 is less likely to approach the second seal ring 123. Thus, the semiconductor device A1 has an advantage of reducing the occurrence of dielectric breakdown.

In the semiconductor device A1, the bump-stacked body 2 is formed between the second semiconductor element 12 and the bonding portion 412. As an example, the bonding portion 412 may be formed by a second bonding. Typically, in second bonding, forces are applied to cut the wire. Such forces may cause failures in the bonded object. In the present embodiment, the bump-stacked body 2 on the bonding portion 412 receive such a force, so that no force is applied directly to the second semiconductor element 12. Thus, the occurrence of failures due to the bonding of the first wire 41 may be reduced.

In the semiconductor device A1, the bump-stacked body 2 may be formed by the same method as the connection members 4. Specifically, the bump 21 and the first wire 41 may be formed by ball bonding. Such a configuration does not need additional equipment to configure the bonding portions 411 and 412 in different positions. Thus, the semiconductor device A1 has an advantage of improving dielectric strength at a lower cost.

In the semiconductor device A1, the first semiconductor element 11 includes the first lower winding 115b of the first functional portion 115 with the same (or generally same) potential as the potential of the first lead 31. The first semiconductor element 11 is bonded to the first lead 31, so that the first semiconductor substrate 110 has the same (or generally same) potential as the first lead 31. Hence, the semiconductor substrate 110 shares the same potential as the first lower winding 115b. Thus, in the semiconductor device A1, the number of insulative layers 1171 between the first semiconductor substrate 110 and the first lower winding 115b may be reduced, thereby reducing the thickness of the first semiconductor element 11.

In the semiconductor device A1, the second wire 42 is connected to the pad 111 electrically connected to the first lower winding 115b, so that the first lower winding 115b is electrically connected to the third semiconductor element 13. The third semiconductor element 13 is bonded to the first lead 31. Such a configuration results in that the first circuit includes the first lower winding 115b and the first lead 31 together with the third semiconductor element 13. In other words, the semiconductor device A1 has an advantage of making the potential of the first lower winding 115b the same as that of the first lead 31.

In the semiconductor device A1, the second semiconductor element 12 includes the second lower winding 125b of the second functional portion 125 with the same (or generally same) potential as the potential of the second lead 32. The second semiconductor element 12 is bonded to the second lead 32, so that the second semiconductor substrate 120 has the same (or generally same) potential as the second lead 32. Hence, the second semiconductor substrate 120 shares the same potential as the second lower winding 125b. Thus, in the semiconductor device A1, the number of insulative layers 1271 between the second semiconductor substrate 120 and the second lower winding 125b may be reduced, thereby reducing the thickness of the second semiconductor element 12.

In the semiconductor device A1, the third wire 43 is connected to the pad 121 electrically connected to the second lower winding 125b, so that the second lower winding 125b is electrically connected to the fourth semiconductor element 14. The fourth semiconductor element 14 is bonded to the second lead 32. Such a configuration results in that the second circuit includes the second lower winding 125b and the second lead 32 together with the fourth semiconductor element 14. In other words, In the semiconductor device A1 has an advantage of making the potential of the second lower winding 125b the same as that of the second lead 32.

Semiconductor devices according to other embodiments and variations of the present disclosure are described below. In these figures, elements identical or similar to the above embodiment are denoted by the same reference signs as those of the above embodiment, and redundant explanations are omitted. Various parts of embodiments may be selectively used in any appropriate combination as long as it is technically compatible.

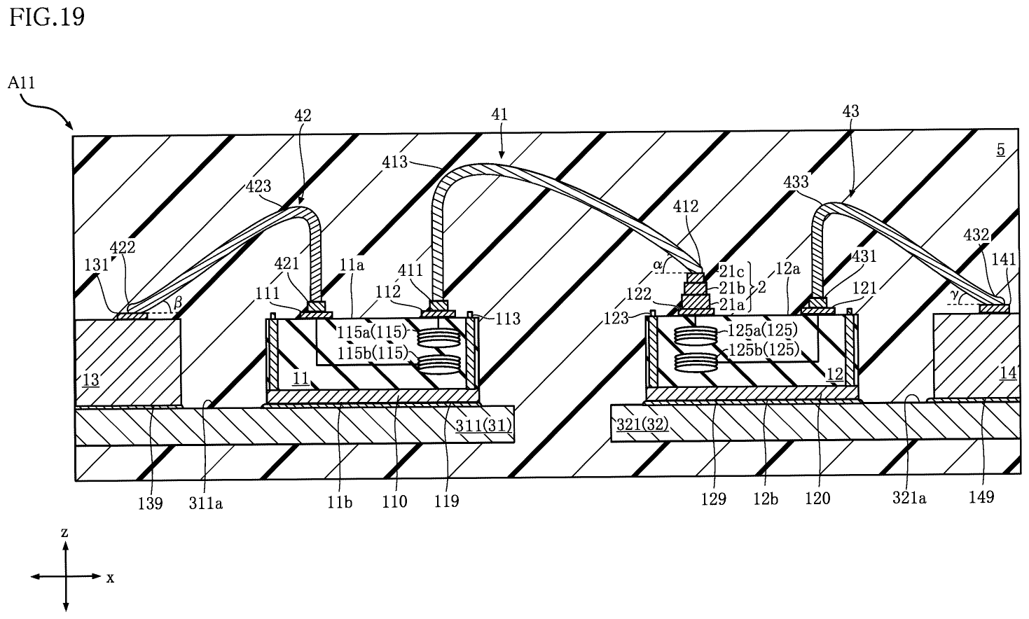

FIG. 19 shows a semiconductor device A11 according to a first variation of the first embodiment. FIG. 19 is a sectional view of a part of the semiconductor device A11. The semiconductor device A11 differs from the semiconductor device A1 in the configuration of at least one of the bump-stacked bodies 2.

The semiconductor device A11 includes, as with the semiconductor device A1, the bump-stacked body 2 that is bonded to the pad 122 of the second semiconductor element 12 and the bonding portion 412 of the first wire 41. However, unlike the semiconductor device A1, the sizes of the bumps 21 of the bump-stacked body 2 are different from each other. In the illustrated example, the first bump 21a is greater than the second bump 21b, and the second bump 21b is greater than the third bump 21c. In plan view, the first bump 21a surrounds the second bump 21b and the second bump 21b surrounds the third bump 21c. In other words, in plan view, the area of the first bump 21a is greater than the area of the second bump 21b, and the area of the second bump 21b is greater than the area of the third bump 21c. As understood from this example, the bump-stacked body 2 may be configured such that the area of the bumps 21 increases from bonding portion 412 to pad 122.

In the semiconductor device A11, the area of the bumps 21 in the bump-stacked body 2 increases from the bonding portion 412 to the pad 122. Such a configuration may stabilize the bump-stacked body 2 so that it does not collapse even if the centers of gravity of the bumps 21 are misaligned with each other. Therefore, the semiconductor device A11 may more stably realize a configuration in which dielectric breakdown is reduced. In addition, the semiconductor device A11 may have a configuration in common with the semiconductor device A1, thereby achieving the same effect as the semiconductor device A1.

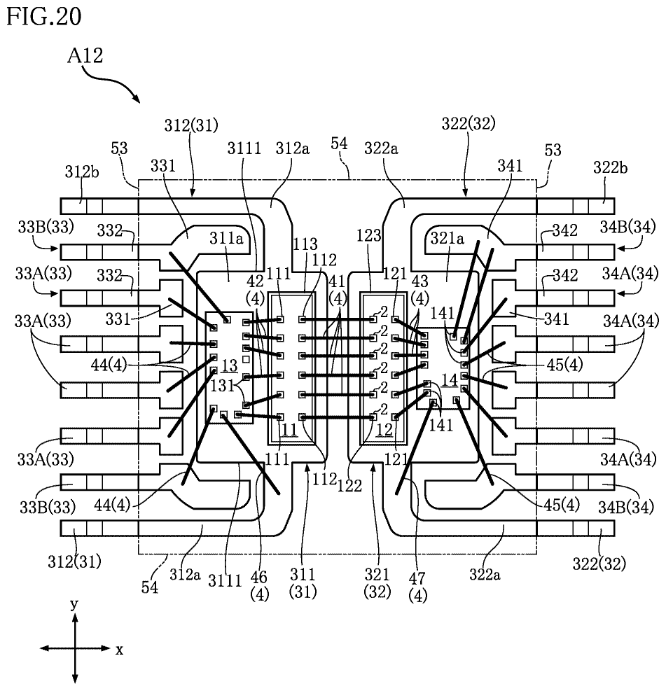

FIG. 20 shows a semiconductor device A12 according to a second variation of the first embodiment. The semiconductor device A12 differs from the semiconductor device A1 in the first lead 31 and the second lead 32.

In the semiconductor device A12, the two first terminal portions 312 of the first lead 31 are connected to the first island portion 311. More specifically, the first island portion 311 includes two ends 3111 spaced apart from each other in the second direction y, and the two first terminal portions 312 are connected to the respective two ends 3111. Each of the two first terminal portions 312 includes the covered portion 312a and the exposed portion 312b. Each of the covered portions 312a includes the outer portion 312a1 and the inclined portion 312a2. Similarly, the second lead 32 includes the second island portion 321 with two ends 3111 spaced apart from each other in the second direction y and the two second terminal portions 322 connected to the respective two ends 3111. Each of the two second terminal portions 322 includes the covered portion 322a and the exposed portion 322b. Each of the covered portions 322a includes the outer portion 322a1 and the inclined portion 322a2.

In the semiconductor device A12, the first island portion 311 is connected to the two first terminal portions 312. According to this configuration, the stress on the first island portion 311 is distributed to the two ends 3111 in the second direction y compared to the case where the one first terminal portion 312 is connected to the first island portion 311. Thus, the first lead 31 is more resistant to deformation. Similarly, the second lead 32 is more difficult to deform due to the connections between the second island portion 321 and the two second terminal portions 322. In addition, the semiconductor device A12 may have a configuration in common with the semiconductor device A1, thereby achieving the same effect as the semiconductor device A1.

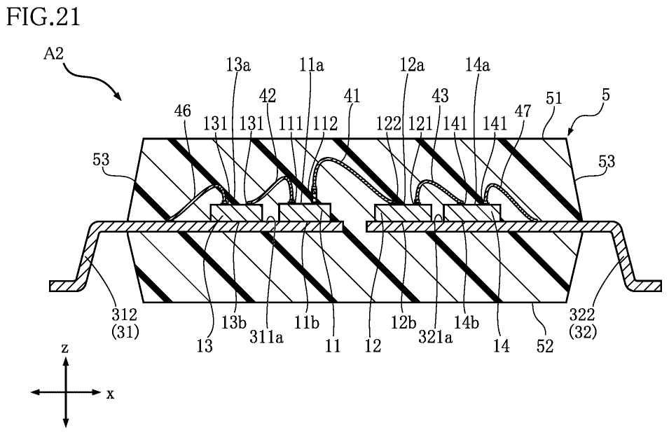

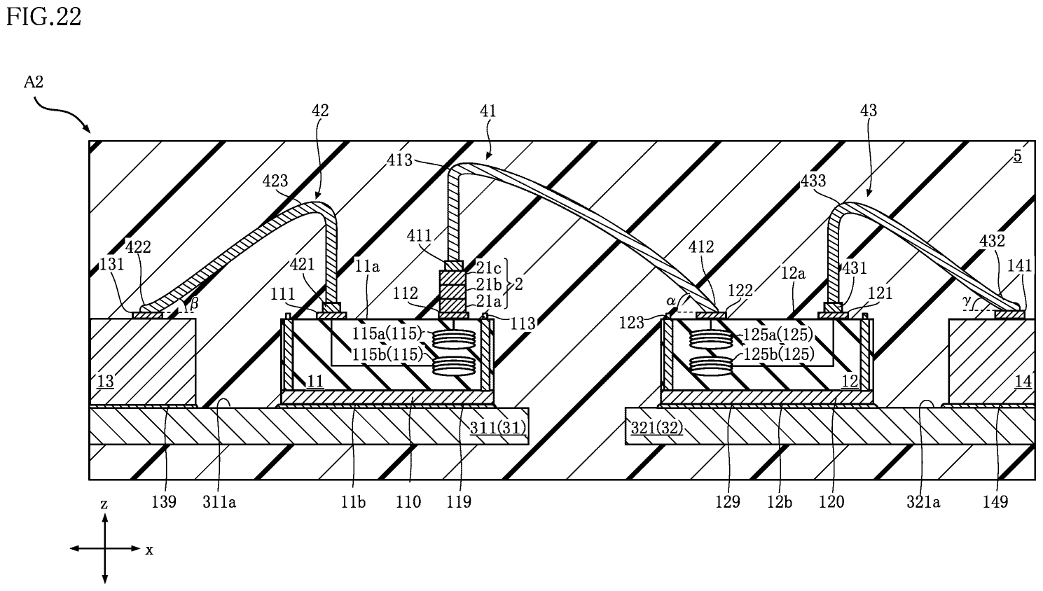

FIGS. 21 and 22 show a semiconductor device A2 according to a second embodiment. The semiconductor device A2 differs from the semiconductor device A1 in the position of the bump-stacked bodies 2.

In the semiconductor device A2, the bump-stacked bodies 2 are formed on the respective pads 112 of the first semiconductor element 11. More specifically, the bump-stacked bodies 2 are bonded to the first semiconductor element 11 and the bonding portion 411. In this case, the distance in the thickness direction z between the bonding portion 411 and the first island portion 311 is greater than the distance in the thickness direction z between the bonding portion 412 and the second island portion 321.

The method for manufacturing the semiconductor device A2 configured as described above is the same as that of the semiconductor device A1 (see FIG. 10), except for the wire bonding step S14. In the wire bonding step S14 of the present embodiment, the bump-stacked bodies 2 are formed on the respective pads 112 of the first semiconductor element 11.

Operative effects of the semiconductor device A2 are as follows.

In the semiconductor device A2, the bonding portion 411 of the first wire 41 is located differently from the bonding portion 412 of the first wire 41 in the thickness direction z, as with the semiconductor device A1. Thus, the first wire 41 has a margin to avoid proximity between the first wire 41 and the first semiconductor element 11 or the second semiconductor element 12. According to this configuration, the semiconductor device A2 has an advantage of reducing the occurrence of dielectric breakdown.

In the semiconductor device A2, the bonding portions 411, which formed by first bonding, are bonded on the respective bump-stacked bodies 2. As described above, the bumps 21 can be formed by cutting only the first bonding of ball bonding. Thus, the bump-stacked bodies 2 and the bonding portions 411 can be formed by continuously forming first bonding on the respective pads 112. Hence, such a configuration reduces the amount of movement needed to form the bump-stacked body 2 and the bonding portion 411. Therefore, the semiconductor device A2 may be manufactured in a simpler way.

In the semiconductor device A2, each bump-stacked body 2 is disposed on the pad 112. The bump-stacked body 2 increases the distance between the bonding portion 411 and the first seal ring 113. Such a configuration may reduce the occurrence of dielectric breakdown between the first wire 41 and the first seal ring 113. In addition, the semiconductor device A2 may have a configuration in common with the semiconductor devices A1 to A12, thereby achieving the same effect as the semiconductor devices A1 to A12.

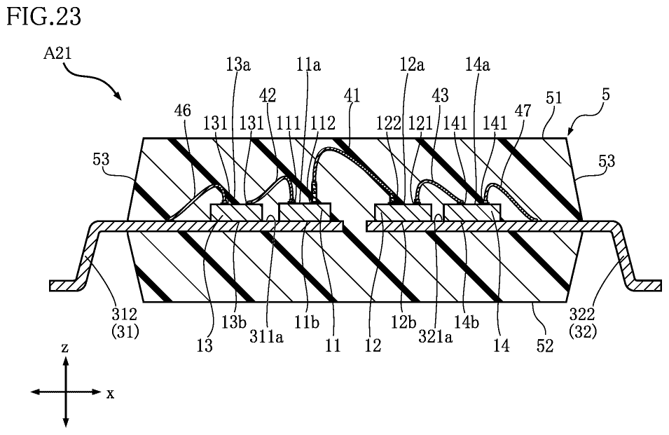

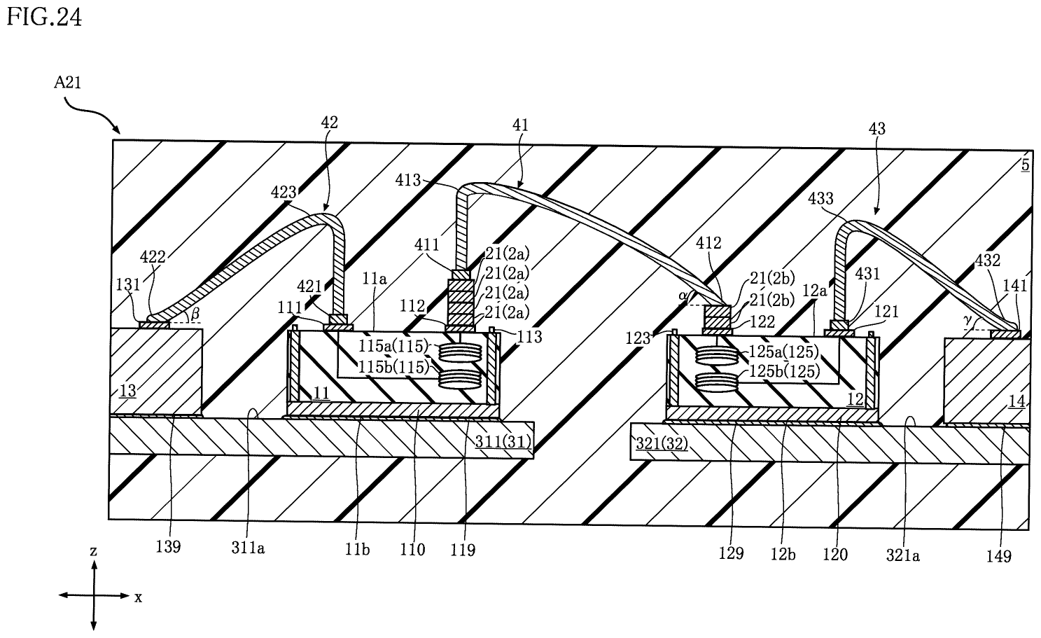

FIGS. 23 and 24 show a semiconductor device A21 according to a first variation of the second embodiment. The semiconductor device A21 differs from the semiconductor device A2 in that the bump-stacked body 2 are also provided on the second semiconductor element 12.

In the semiconductor device A21, the bump-stacked bodies 2 include a first bump-stacked body 2a and a second bump-stacked body 2b. The first bump-stacked body 2a is bonded to the first semiconductor element 11 and the bonding portion 411. The second bump-stacked body 2b is bonded to the second semiconductor element 12 and the bonding portion 412. The first bump-stacked body 2a is configured such that the thickness (in thickness direction z) of the first bump-stacked body 2a is greater than the thickness of the second bump-stacked body 2b. Such a configuration may be achieved by the difference of the size of each bump 21 or the number of stacked bumps 21.

In the illustrated example, the number of the bumps 21 in the first bump-stacked body 2a is greater than the number of the bumps 21 in the second bump-stacked body 2b. Specifically, four bumps 21 are stacked in the first bump-stacked body 2a and two bumps 21 are stacked in the second bump-stacked body 2b. Further, the thickness of each bump 21 is the same. Unlike this example, the first bump-stacked body 2a and the second bump-stacked body 2b may have the same number of bumps 21 with the thickness of the bumps 21 different from each other. Specifically, the thickness of each bump 21 in the first bump-stacked body 2a may be greater than the thickness of each bump 21 in the second bump-stacked body 2b. In this example, the first bump-stacked body 2a and the second bump-stacked body 2b may each consist of one bump 21.

The method for manufacturing the semiconductor device A21 configured as described above is the same as that of the semiconductor device A1 (see FIG. 10), except for the wire bonding step S14. In the wire bonding step S14 of the present embodiment, the bump-stacked bodies 2 are formed on at least one of the respective pads 112 of the first semiconductor element 11 and at least one of the respective pads 122 of the second semiconductor element 12. In this case, the bump-stacked bodies 2 may be formed in any sequence.

In the semiconductor device A21, the first bump-stacked body 2a is located on the pad 112 and the second bump-stacked body 2b is located on the pad 122. The first bump-stacked body 2a increases the distance between the bonding portion 411 and the first seal ring 113, and the second bump-stacked body 2b increases the distance between the bonding portion 412 and the second seal ring 123. Such a configuration reduces the occurrence of dielectric breakdown between the first wire 41 and both the first seal ring 113 and the second seal ring 123. In addition, the semiconductor device A21 may have a configuration in common with the semiconductor devices A1 to A2, thereby achieving the same effect as the semiconductor devices A1 to A2.

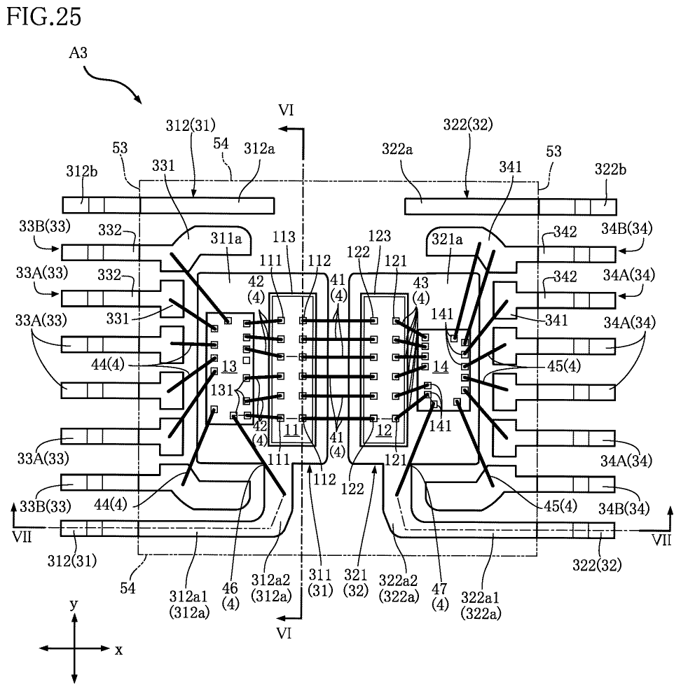

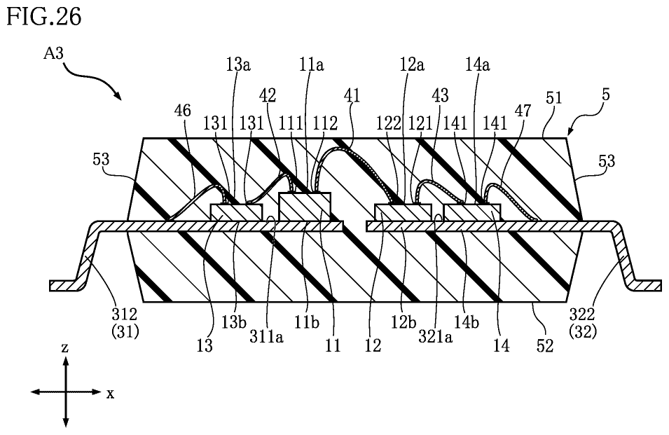

FIGS. 25 to 27 show a semiconductor device A3 according to a third embodiment. The semiconductor device A3 differs from the semiconductor device A1 in that it does not have the bump-stacked bodies 2 and the thicknesses of the first semiconductor element 11 and the second semiconductor element 12 are different from each other. In the present embodiment, the bonding portions 412 of the first wires 41 are bonded to the respective pads 122. Further, in the present embodiment, the third circuit does not include the bump-stacked bodies 2. The method for manufacturing the semiconductor device A3 is the same as that of the method for manufacturing the semiconductor device A1 (see FIG. 10), except that the bump-stacked bodies 2 are not formed in the wire bonding step S14.

In the illustrated example, the dimension in the thickness direction z of the first semiconductor element 11 is greater than the dimension in the thickness direction z of the second semiconductor element 12. More specifically, the dimension in the thickness direction z of the first semiconductor substrate 110 of the first semiconductor element 11 is greater than the dimension in the thickness direction z of the second semiconductor substrate 120 of the second semiconductor element 12. In the thickness direction z, the spacing between at least one pair of the first upper winding 115a and the first lower winding 115b may be equal to the spacing between at least one pair of the second upper winding 125a and the second lower winding 125b. Unlike this example, the dimension in the thickness direction z of the plurality of insulative layers 1171 of the first semiconductor element 11 may be greater than the dimension in the thickness direction z of the plurality of the insulative layers 1271 of the second semiconductor element 12. Such a configuration may also make the first semiconductor element 11 thicker than the second semiconductor element 12. In this case, the number of the insulative layers 1171 may be greater than the number of the insulative layers 1271. In the illustrated example, the first semiconductor element 11 is thicker than the third semiconductor element 13 and the fourth semiconductor element 14 as well as the second semiconductor element 12. Additionally, the second semiconductor element 12, the third semiconductor element 13, and the fourth semiconductor element 14 may share the same thickness.

Operative effects of the semiconductor device A3 are as follows.

In the semiconductor device A3, the first semiconductor element 11 is thicker than the second semiconductor element 12, so that the bonding portion 411 of the first wire 41 is located differently from the bonding portion 412 of the first wire 41 in the thickness direction z. Thus, the first wire 41 has a margin to avoid the proximity between the first wire 41 and the second semiconductor element 12. According to this configuration, the semiconductor device A3 has an advantage of reducing the occurrence of dielectric breakdown.

The first functional portion 115 may adopt the same functional configuration as the second functional portion 125. For example, the thicknesses of the first semiconductor element 11 and the second semiconductor element 12 are different by making the thicknesses of the first semiconductor substrate 110 different from the second semiconductor substrate 120. In this case, the distance between the first upper winding and the second lower winding may be equal to each other. Therefore, it is possible to change the semiconductor device A3 so that the first functional portion 115 of the first semiconductor element 11 and the second functional portion 125 of the second semiconductor element 12 have similar insulation characteristics.

In the semiconductor device A3, the number of the insulative layer 1171 in the first functional portion 115 may be greater than the number of the insulative layer 1271 in the second functional portion 125 in order to make the first semiconductor element 11 thicker than the second semiconductor element 12. Such a configuration enhances the insulation characteristics in the first semiconductor element 11.

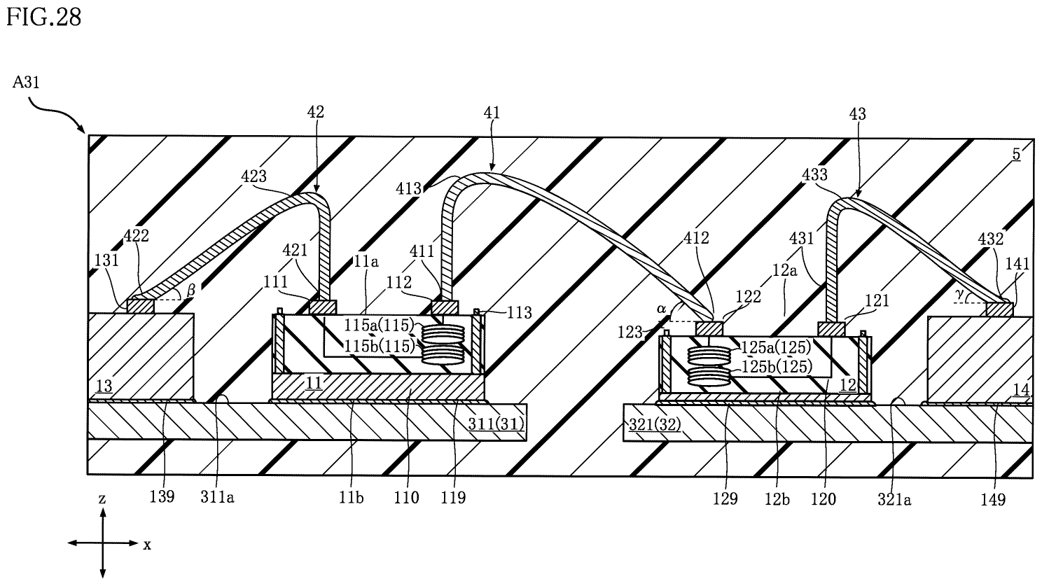

FIG. 28 shows s semiconductor device A31 according to a first variation of the third embodiment. FIG. 28 is a sectional view of a part of the semiconductor device A31, and the parts not shown may be configured in the same manner as the semiconductor device A3. The semiconductor device A31 differs from the semiconductor device A3 in the first semiconductor element 11 and the second semiconductor element 12.

In the semiconductor device A31, the thickness of the first semiconductor element 11 is greater than the thickness of the second semiconductor element 12, as with the semiconductor device A3. On the other hand, unlike the semiconductor device A3, the thickness of the second semiconductor element 12 is smaller than the thickness of each of the first semiconductor element 11, the third semiconductor element 13, and the fourth semiconductor element 14. In the illustrated example, the thickness of the second semiconductor substrate 120 is smaller than the thickness of the first semiconductor substrate 110. The first functional portion 115 may adopt the same functional configuration as the second functional portion 125 (e.g., the distance between the first upper winding and the second lower winding may be equal to each other). Alternatively, the number of the insulative layers 1271 may be less than the number of the insulative layers 1171.

In the semiconductor device A31, the bonding portion 411 of the first wire 41 is located differently from the bonding portion 412 of the first wire 41 in the thickness direction z. Thus, the first wire 41 has a margin to avoid the proximity between the first wire 41 and the second semiconductor element 12. According to this configuration, the semiconductor device A31 has an advantage of reducing the occurrence of dielectric breakdown. In addition, the semiconductor device A31 may have a configuration in common with the semiconductor devices A1 to A3, thereby achieving the same effect as the semiconductor devices A1 to A3.

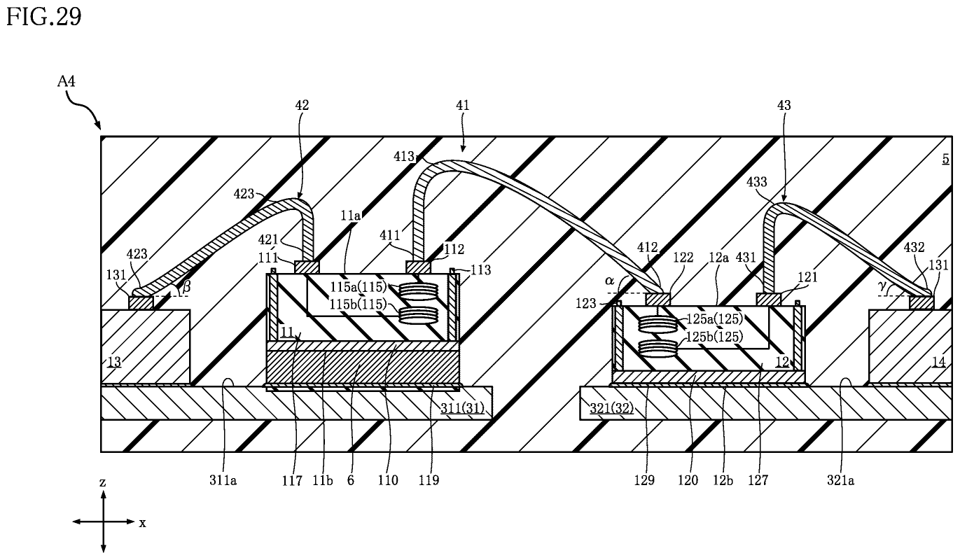

FIG. 29 shows a semiconductor device A4 according to a fourth embodiment. FIG. 29 is a sectional view of a part of the semiconductor device A4, and the parts not shown may be configured in the same manner as the semiconductor device A3. The semiconductor device A4 differs from the semiconductor device A3 in that the first semiconductor element 11 has the same thickness as the second semiconductor element 12. Further, the semiconductor device A4 further includes a spacer 6. The method for manufacturing the semiconductor device A4 is the same as that of the semiconductor device A1 (see FIG. 10) except that the bump-stacked bodies 2 are not formed in the wire bonding step S14 and that the spacer 6 is provided in predetermined locations in the lead frame processing step S12 or the element mounting step S13.

In the semiconductor device A4, the spacer 6 is disposed between the first semiconductor element 11 and the first lead 31. The spacer 6 is sandwiched between the first reverse face 11b and the first mount face 311a. In other words, the first semiconductor element 11 is mounted on the first lead 31 via the spacer 6. In the illustrated example, the spacer 6 is bonded to the first reverse face 11b and the first mount face 311a by the first conductive bonding material 119. The shape of the spacer 6 is not particularly limited and may be a cuboid or a cylinder. The size of the spacer 6 is also not particularly limited. As an example, the spacer 6 may have a surface facing the first reverse face 11b with the same size as the first reverse face 11b. As another example, the spacer 6 may have a surface facing the first mount face 311a with the same size as the first mount face 311a. Further, the number of spacers 6 is not limited. In the illustrated example, one spacer 6 is provided, but it may be divided into a plurality of spacers 6.

The spacer 6 contains metal (e.g., cupper). In this case, the spacer 6 is electrically connected to the first lead 31. Alternatively, the spacer 6 includes a synthetic resin. In this case, the spacer 6 is insulated from the first lead 31, so that the potential is different between the first semiconductor element 11 and the first lead 31. As an example, the spacer 6 may be formed from a single component. Alternatively, the spacer 6 may be formed from multiple members integrally. For example, the spacer 6 may be formed by bonding a plurality of rectangular-shaped metal ingots into a stack.

Operative effects of the semiconductor device A4 are as follows.

In the semiconductor device A4, although the first semiconductor element 11 and the second semiconductor element 12 have the same thickness, the spacer 6 is located under the first semiconductor element 11, so that the bonding portion 411 of the first wire 41 is located differently from the bonding portion 412 of the first wire 41 in the thickness direction z. Thus, the first wire 41 has a margin to avoid the proximity between the first wire 41 and the second semiconductor element 12. According to this configuration, the semiconductor device A4 has an advantage of reducing the occurrence of dielectric breakdown. Further, the semiconductor device A4 has an advantage of being more cost-effective because it does not need semiconductor elements of different sizes. In addition, the semiconductor device A4 may have a configuration in common with the semiconductor devices A1 to A31, thereby achieving the same effect as the semiconductor devices A1 to A31.

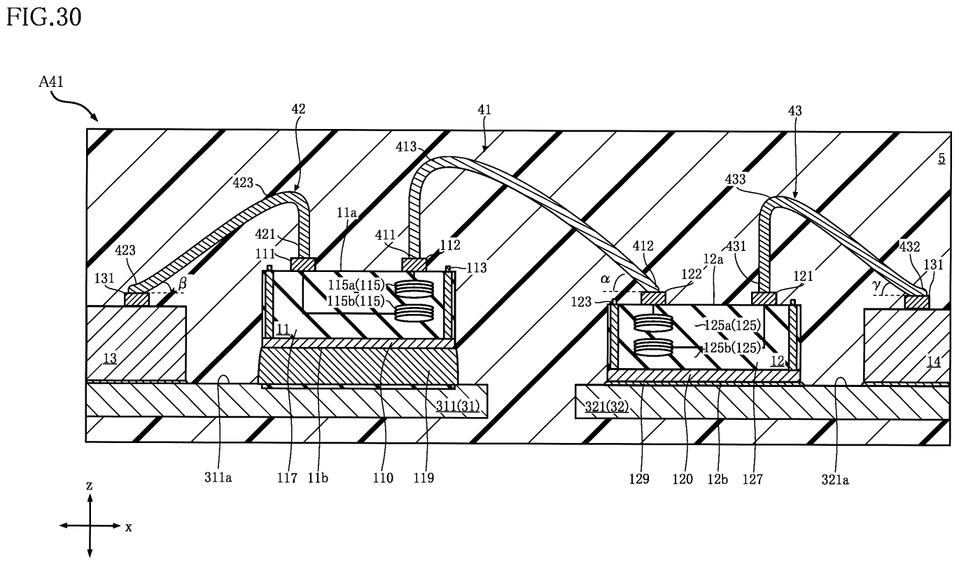

FIG. 30 shows a semiconductor device A41 according to a first variation of the fourth embodiment. FIG. 30 is a sectional view of a part of the semiconductor device A41, and the parts not shown may be configured in the same manner as the semiconductor device A3. The semiconductor device A41 differs from the semiconductor device A4 in that it does not have the spacer 6 and the thicknesses of the first conductive bonding material 119 and the second conductive bonding material 129 are different.

In the semiconductor device A41, although the thicknesses of the first semiconductor element 11 and the second semiconductor element 12 are the same, the thickness of the first conductive bonding material 119 is greater than that of the second conductive bonding material 129. Hence, the bonding portion 411 of the first wire 41 is located differently from the bonding portion 412 of the first wire 41 in the thickness direction z. Thus, the first wire 41 has a margin to avoid the proximity between the first wire 41 and the second semiconductor element 12. According to this configuration, the semiconductor device A41 has an advantage of reducing the occurrence of dielectric breakdown. Further, the semiconductor device A41 has an advantage of being more cost-effective, as with the semiconductor device A4. In addition, the semiconductor device A41 may have a configuration in common with the semiconductor devices A1 to A4, thereby achieving the same effect as the semiconductor devices A1 to A4.

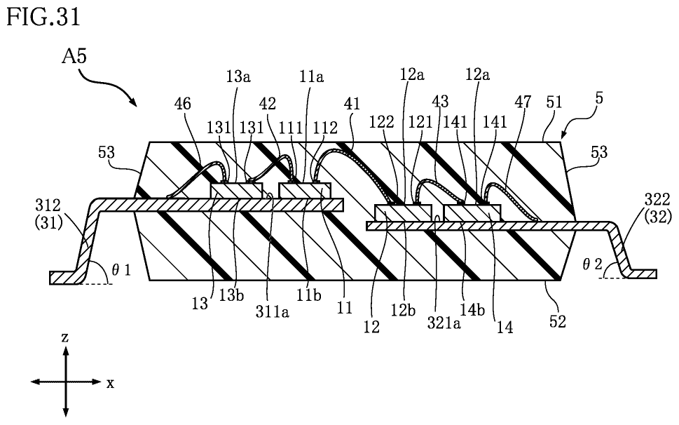

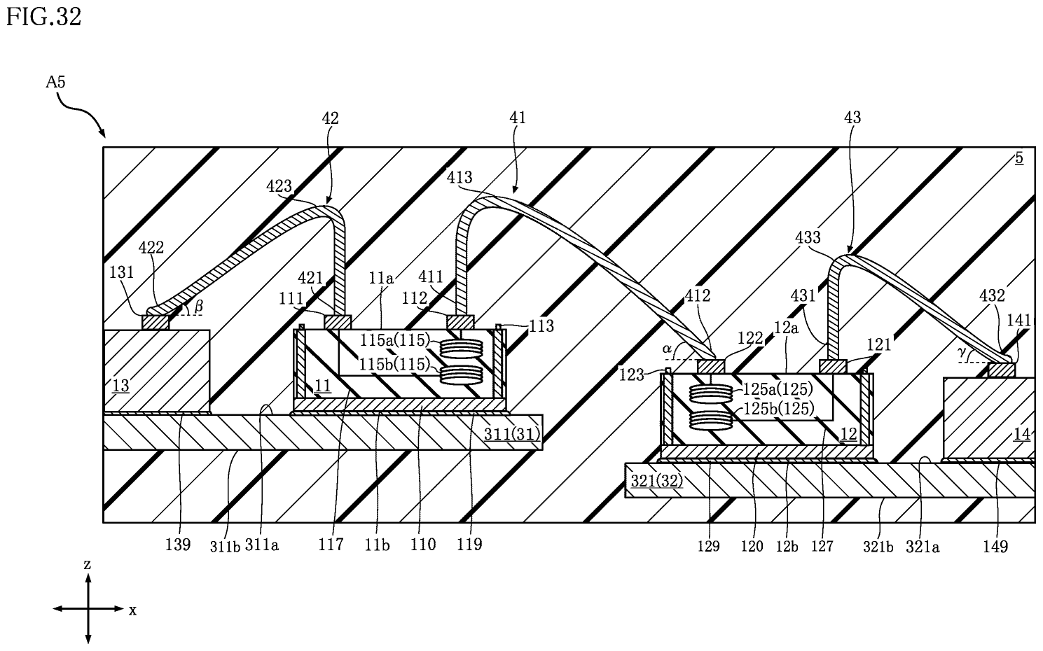

FIGS. 31 and 32 show a semiconductor device A5 according to a fifth embodiment. FIGS. 31 and 32 are sectional views each showing a part of the semiconductor device A5, and the parts not shown may be configured in the same manner as the semiconductor device A3. The semiconductor device A5 differs from the semiconductor device A3 in the first lead 31 and the second lead 32. The method for manufacturing the semiconductor device A5 is the same as that of the semiconductor device A1 (see FIG. 10), except that the bump-stacked bodies 2 are not formed in the wire bonding step S14.

In the semiconductor device A5, the positions of the first island portion 311 and the second island portion 321 in the thickness direction z are different from each other. Thus, the positions of the first mount face 311a and the second mount face 321a in the thickness direction z are different from each other. Also, the positions of the first lead reverse face 311b and the second lead reverse face 321b in the thickness direction z are different from each other. More specifically, the distance between the first mount face 311a and the top face 51 is smaller than the distance between the second mount face 321a and the top face 51. As an example, such a configuration may be achieved by making the first terminal portion 312 bend more gently than the second terminal portion 322. More specifically, an angle θ1 at the bent portion in the covered portion 312a of the first terminal portion 312 is greater than an angle θ2 at the bent portion in the covered portion 322a of the second terminal portion 322. In the present embodiment, the first semiconductor element 11 may have the same thickness as the second semiconductor element 12.

Operative effects of the semiconductor device A5 are as follows.

In the semiconductor device A5, the positions of the first mount face 311a and the second mount face 321a in the thickness direction z differ from each other. Hence, the bonding portion 411 of the first wire 41 is located differently from the bonding portion 412 of the first wire 41 in the thickness direction z. Thus, the first wire 41 has a margin to avoid the proximity between the first wire 41 and the second semiconductor element 12. According to this configuration, the semiconductor device A5 has an advantage of reducing the occurrence of dielectric breakdown. In addition, the semiconductor device A5 may have a configuration in common with the semiconductor devices A1 to A41, thereby achieving the same effect as the semiconductor devices A1 to A41.

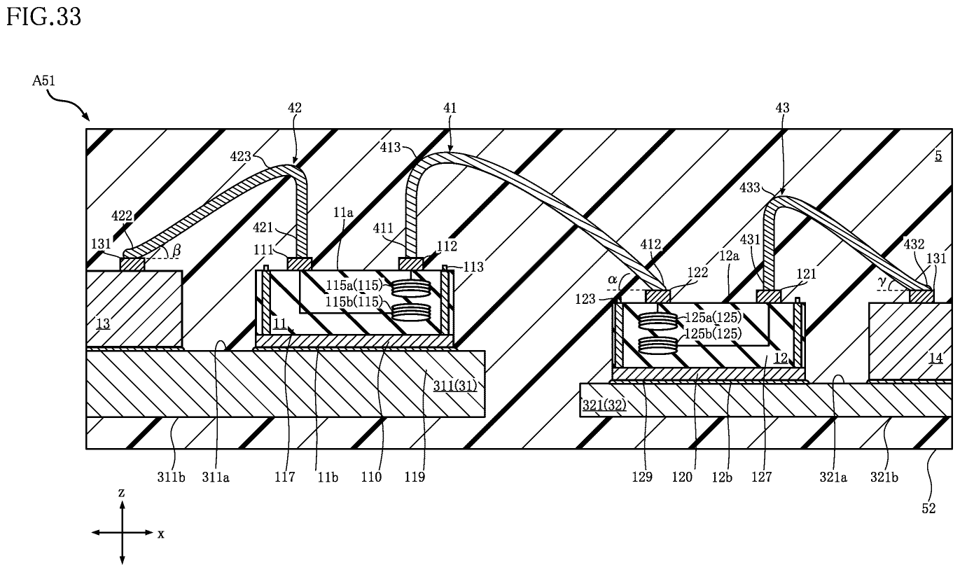

FIG. 33 shows a semiconductor device A51 according to a first variation of the fifth embodiment. FIG. 33 is a sectional view of a part of the semiconductor device A51, and the parts not shown may be configured in the same manner as the semiconductor device A3. The semiconductor device A51 differs from the semiconductor device A5 in the first lead 31 and the second lead 32.

The semiconductor device A51 includes the first island portion 311 with the thickness greater than the thickness of the second island portion 321. In the illustrated example, the first lead reverse face 311b overlaps with the second lead reverse face 321b in the first direction x.

In the semiconductor device A51, the positions of the first mount face 311a and the second mount face 321a in the thickness direction z are different from each other, as with the semiconductor device A5. Hence, the bonding portion 411 of the first wire 41 is located differently from the bonding portion 412 of the first wire 41 in the thickness direction z. Thus, the first wire 41 has a margin to avoid the proximity between the first wire 41 and the second semiconductor element 12. According to this configuration, the semiconductor device A51 has an advantage of reducing the occurrence of dielectric breakdown. In addition, the semiconductor device A51 may have a configuration in common with the semiconductor devices A1 to A5, thereby achieving the same effect as the semiconductor devices A1 to A5.

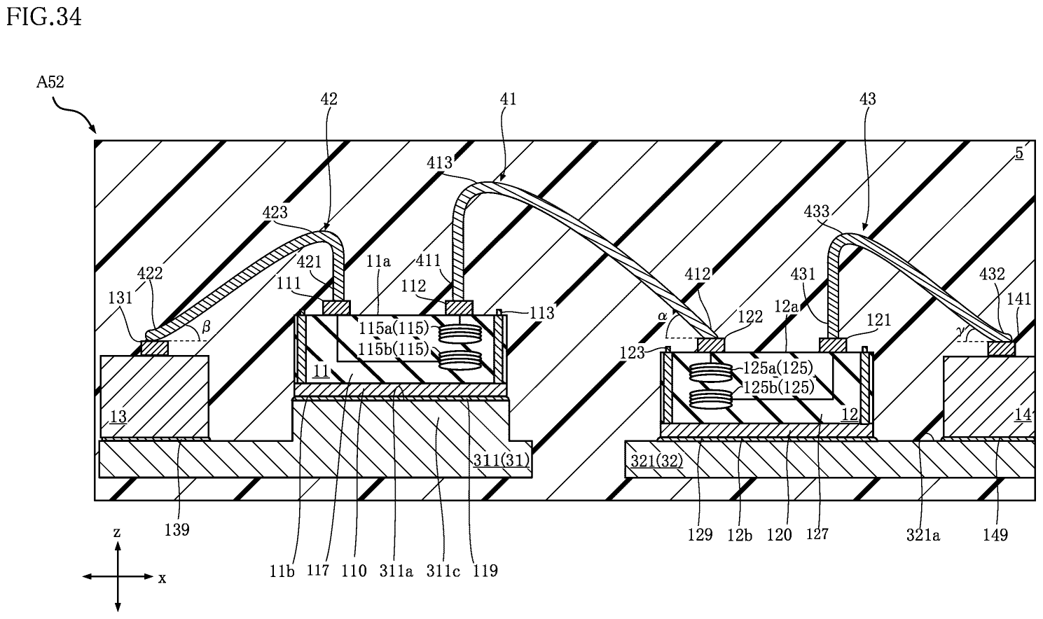

FIG. 34 shows a semiconductor device A52 according to a second variation of the fifth embodiment. FIG. 34 is a sectional view of a part of the semiconductor device A52, and the parts not shown may be configured in the same manner as the semiconductor device A3. The semiconductor device A52 differs from the semiconductor device A5 in the first lead 31 and the second lead 32.

In the semiconductor device A52, the first island portion 311 of the first lead 31 includes a raised portion 311c protruding in the thickness direction z at the first mount face 311a. The raised portion 311c has a surface with the different position from the second mount face 321a in the thickness direction z. The first lead reverse face 311b overlaps with the second lead reverse face 321b in the first direction x, as with the semiconductor device A51.

The raised portion 311c may be formed by the following method, for example. In the lead frame preparation step S11, after masking a part of the lead frame 81, the raised portion 311c may be formed in the masked part by etching.

In the semiconductor device A52, the positions of the first mount face 311a and the second mount face 321a in the thickness direction z are different from each other, as with the semiconductor device A5. Hence, the bonding portion 411 of the first wire 41 is located differently from the bonding portion 412 of the first wire 41 in the thickness direction z. Thus, the first wire 41 has a margin to avoid the proximity between the first wire 41 and the second semiconductor element 12. According to this configuration, the semiconductor device A52 has an advantage of reducing the occurrence of dielectric breakdown. In addition, the semiconductor device A52 may have a configuration in common with the semiconductor devices A1 to A51, thereby achieving the same effect as the semiconductor devices A1 to A51.

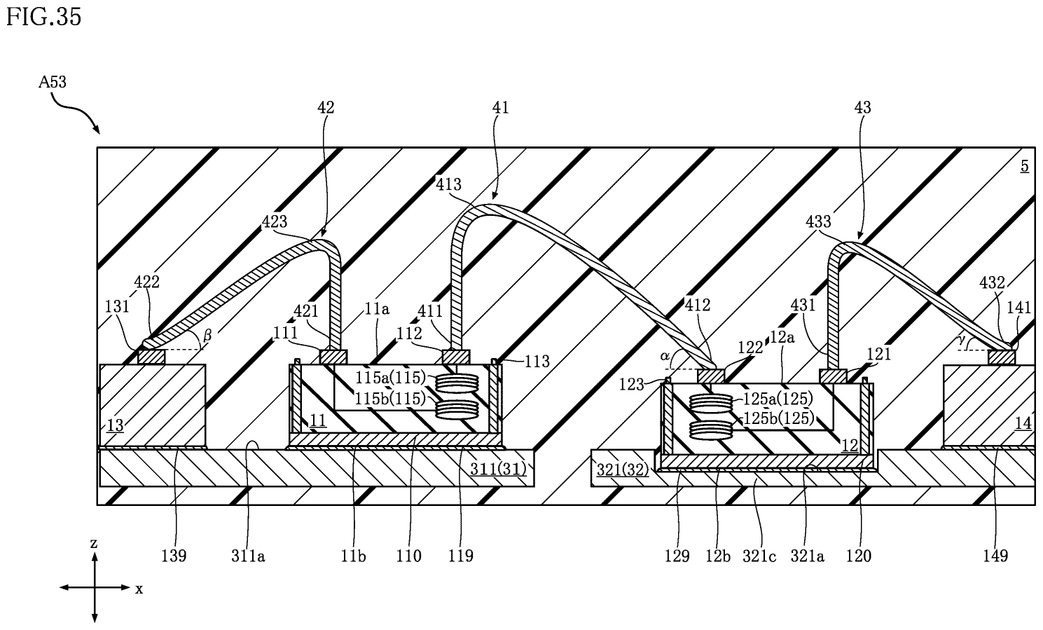

FIG. 35 shows a semiconductor device A53 according to a third variation of the fifth embodiment. FIG. 35 is a sectional view of a part of the semiconductor device A53, and the parts not shown may be configured in the same manner as the semiconductor device A3. The semiconductor device A53 differs from the semiconductor device A5 in the first lead 31 and the second lead 32.

In the semiconductor device A53, the second island portion 321 of the second lead 32 includes a recessed portion 321c recessed in the thickness direction z at the second mount face 321a. In the semiconductor device A53, the positions of the first mount face 311a and the second mount face 321a in the thickness direction z are different from each other, as with the semiconductor device A5. In the semiconductor device A53, the first lead reverse face 311b overlaps with the second lead reverse face 321b in the first direction x, as with the semiconductor device A51.

The recessed portion 321c may be formed by the following method, for example. In the lead frame preparation step S11, after masking a part of the lead frame 81, the recessed portion 321c may be formed in the unmasked part by etching.

In the semiconductor device A53, the positions of the first mount face 311a and the second mount face 321a in the thickness direction z are different from each other, as with the semiconductor device A5. Hence, the bonding portion 411 of the first wire 41 is located differently from the bonding portion 412 of the first wire 41 in the thickness direction z. Thus, the first wire 41 has a margin to avoid the proximity between the first wire 41 and the second semiconductor element 12. According to this configuration, the semiconductor device A53 has an advantage of reducing the occurrence of dielectric breakdown. In addition, the semiconductor device A53 may have a configuration in common with the semiconductor devices A1 to A52, thereby achieving the same effect as the semiconductor devices A1 to A52.

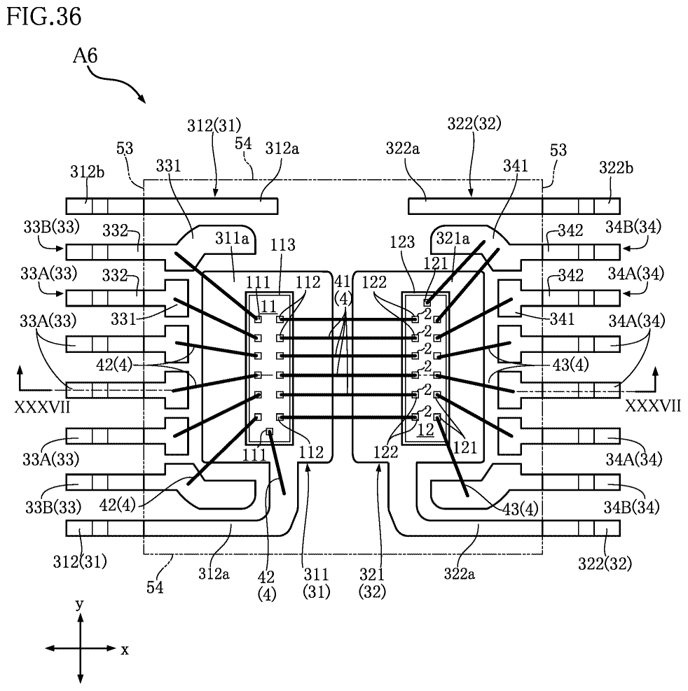

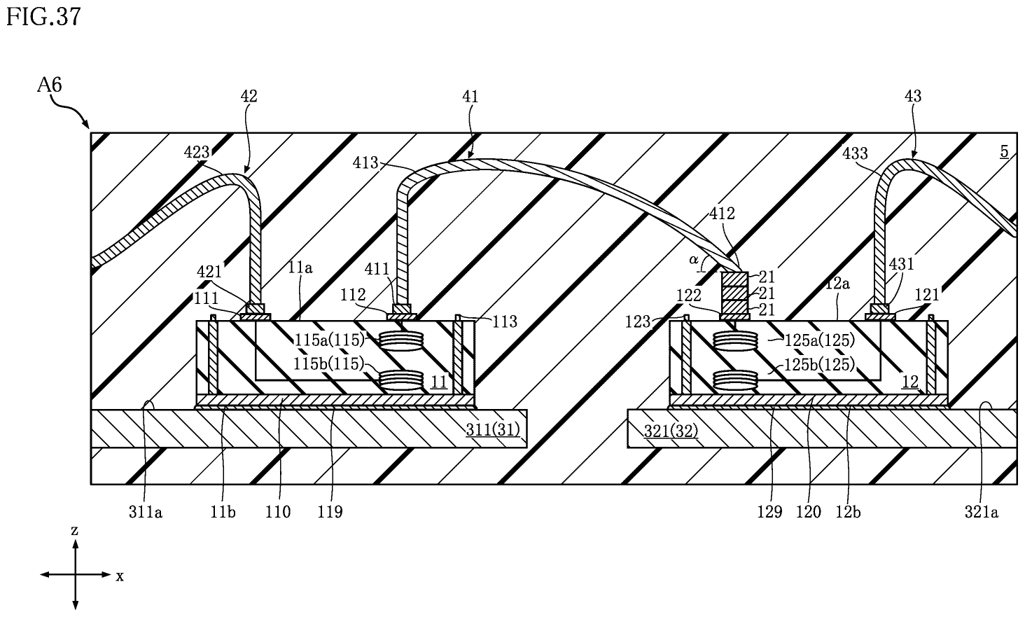

FIGS. 36 and 37 show a semiconductor device A6 according to a sixth embodiment. The semiconductor device A6 differs from the semiconductor device A1 in that it does not include the third semiconductor element 13 and the fourth semiconductor element 14.

In the semiconductor device A6, the second wires 42 are bonded to the respective pads 111 and one of the two first terminal portions 312 of the first lead 31 or one of the third leads 33 so as to electrically connect them. In other words, the second wires 42 electrically connect the first semiconductor element 11 to the first lead 31 or the third leads 33.

In the semiconductor device A6, the third wires 43 are bonded to the respective pads 121 and one of the two second terminal portions 322 of the second lead 32 or one of the fourth leads 34 so as to electrically connect them. In other words, the third wires 43 electrically connect the second semiconductor element 12 to the second lead 32 or the fourth leads 34.

In the semiconductor device A6, the internal angle β (not shown) corresponds to the internal angle between the bonding portion 412 of each second wire 42 and the bonding point of the relevant third lead 33. Also, the internal angle γ (not shown) corresponds to the internal angle between the bonding portion 432 of each third wire 43 and the bonding point of the relevant fourth lead 34. Even in this case, the internal angle α is greater than the internal angle β and the internal angle γ.

In the semiconductor device A6, the third semiconductor element 13 may be disposed on a wiring board on which the semiconductor device A6 is mounted, and the third semiconductor element 13 may be electrically connected to the first semiconductor element 11 via the wiring board and the third leads 33. The first lead 31 may be electrically connected to the ground of the first circuit including the third semiconductor element 13 via the wiring board. Similarly, the fourth semiconductor element 14 may be disposed on the wiring board on which the semiconductor device A6 is mounted, and the fourth semiconductor element 14 may be electrically connected to the second semiconductor element 12 via the wiring board and the fourth leads 34. The second lead 32 may be electrically connected to the ground of the second circuit including the fourth semiconductor element 14 via the wiring board. In such a configuration, the semiconductor device A6 (first semiconductor element 11 and the second semiconductor element 12) may be used to insulate the first circuit (circuit including the third semiconductor element 13) and the second circuit (circuit including the fourth semiconductor element 14).

The method of manufacturing the semiconductor device A6 configured as described above is the same as that of the semiconductor device A1 (see FIG. 10), except for the following steps. First, the element mounting step S13 does not include the step for mounting the third semiconductor element 13 and the fourth semiconductor element 14. Second, the wire bonding step S14 does not include forming the bump-stacked bodies 2, the fourth wires 44, the fifth wires 45, the sixth wire 46 and the seventh wire 47.

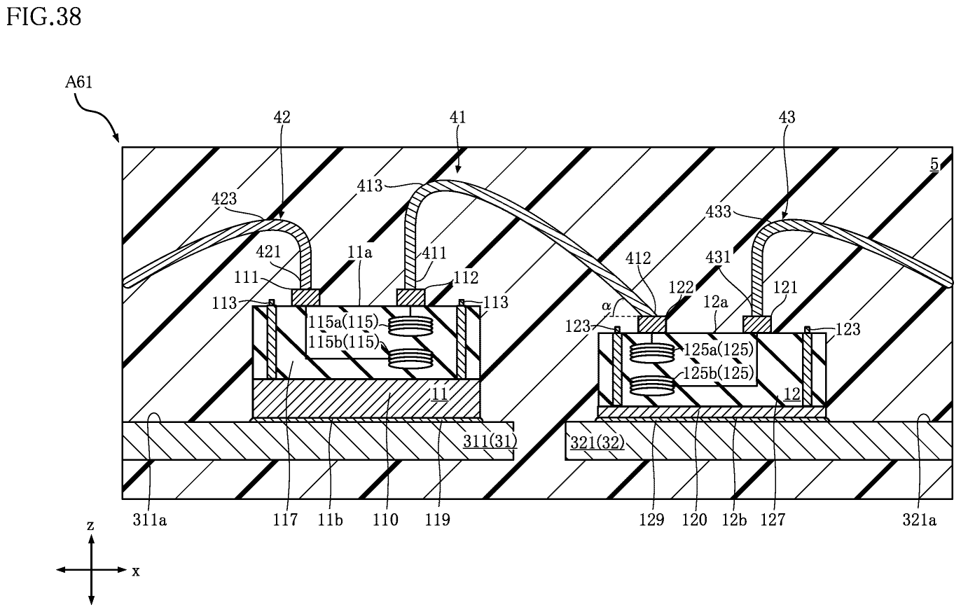

FIG. 38 shows a semiconductor device A61 according to a first variation of the sixth embodiment. FIG. 38 is a sectional view of a part of the semiconductor device A61, and the parts not shown may be configured in the same manner as the semiconductor device A6. The semiconductor device A61 does not include the third semiconductor element 13 and the fourth semiconductor element 14. On the other hand, the semiconductor device A61 does not include the bump-stacked bodies 2 and the thicknesses of the first semiconductor element 11 and the second semiconductor element 12 are different from each other. The first semiconductor element 11 is thicker than the second semiconductor element 12 as with the semiconductor devices A3 and A31.

Operative effects of the semiconductor devices A6 and A61 are as follows.

In the semiconductor devices A6 and A61, the bonding portion 411 of the first wire 41 is located differently from the bonding portion 412 of the first wire 41 in the thickness direction z. Thus, the first wire 41 has a margin to avoid proximity between the first wire 41 and the first semiconductor element 11 or the second semiconductor element 12. Therefore, the semiconductor devices A6 and A61 have an advantage of reducing the occurrence of dielectric breakdown. In addition, the semiconductor devices A6 and A61 may reduce the size of the conductive support member 3 and thus the semiconductor device as a whole due to absences of the third semiconductor element 13 and the fourth semiconductor element 14. In addition, the semiconductor devices A6 and A61 may have a configuration in common with the semiconductor devices A1 to A53, thereby achieving the same effect as the semiconductor devices A1 to A53.

The sixth embodiment shows an example in which the third semiconductor element 13 and the fourth semiconductor element 14 are not provided, but either one of them may be provided. In other words, the semiconductor device of the present disclosure may not be provided with one or both of the third semiconductor element 13 and the fourth semiconductor element 14.

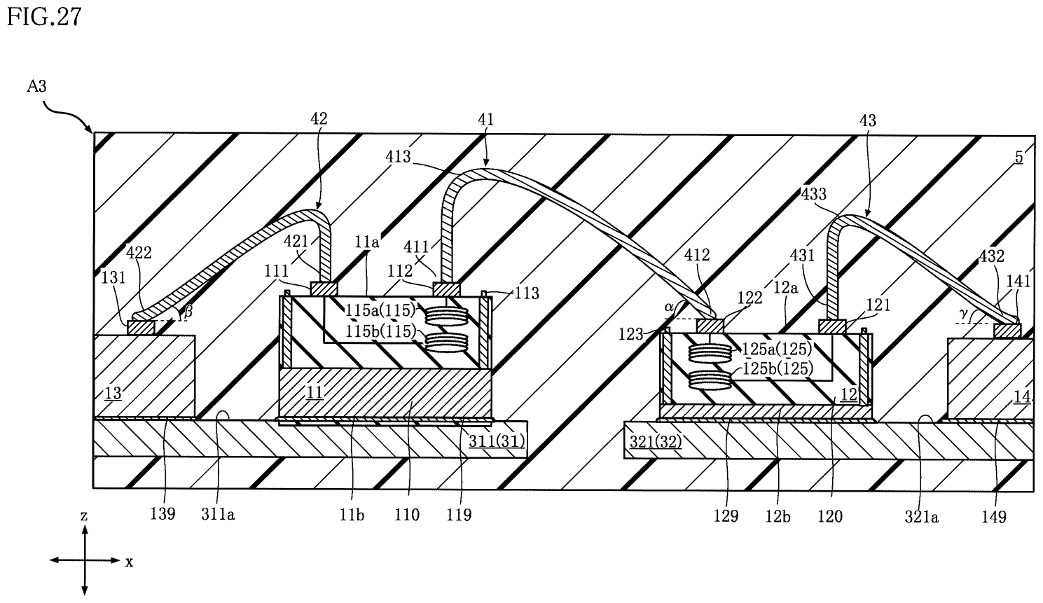

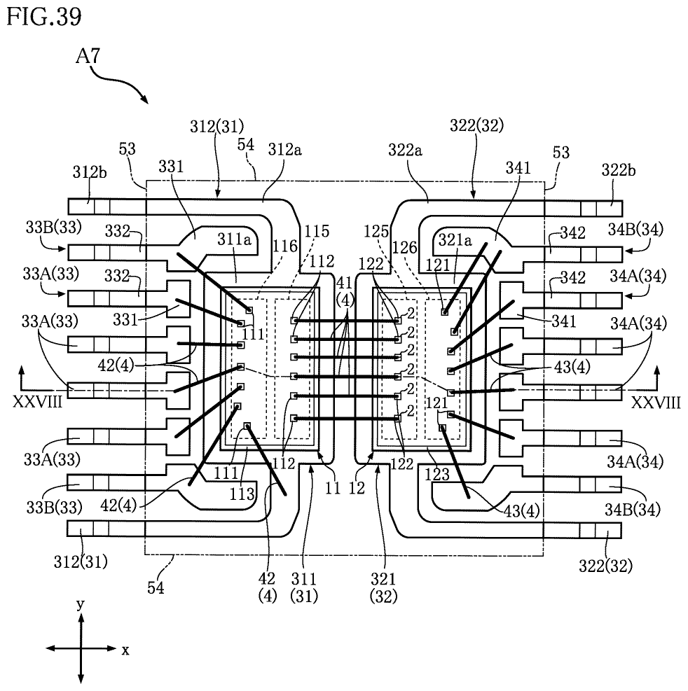

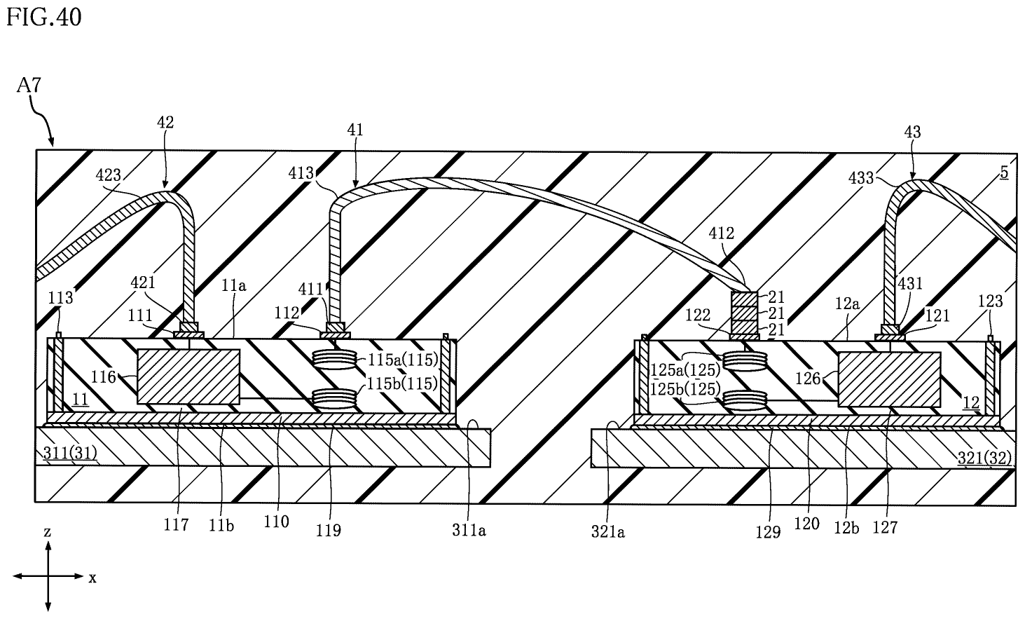

FIGS. 39 and 40 show a semiconductor device A7 according to a seventh embodiment. The semiconductor device A7 differs from the semiconductor device A1 in the following points. First, the first semiconductor element 11 of the semiconductor device A7 includes a third functional portion 116 in addition to the first functional portion 115. Second, the second semiconductor element 12 of the semiconductor device A7 includes a fourth functional portion 126 in addition to the second functional portion 125. The connection of each of the second wires 42 and the third wires 43 is an example and is not limited to the example shown in FIG. 27, and may be changed according to the respective configurations of the first semiconductor element 11 and the second semiconductor element 12.

The third functional portion 116 has the same function as the third semiconductor element 13 (i.e., a control element). The third functional portion 116 may be formed on the first semiconductor substrate 110. The third functional portion 116 is electrically connected to the first functional portion 115 inside the first semiconductor element 11. In the illustrated example, the third functional portion 116 is electrically connected to the first lower winding 115b. In this example, the pads 111 are electrically connected to the third functional portion 116, and the pads 112 are electrically connected to the first functional portion 115 (first upper winding 115a). The first semiconductor element 11 of the semiconductor device A7 is obtained by integrating a control element and an insulating element in a single chip.

The fourth functional portion 126 has the same function as the fourth semiconductor element 14 (i.e., a drive element). The fourth functional portion 126 may be formed on the second semiconductor substrate 120. The fourth functional portion 126 is electrically connected to the second functional portion 125 inside the second semiconductor element 12. In the illustrated example, the fourth functional portion 126 is electrically connected to the second lower winding 125b. In this example, the pads 121 are electrically connected to the fourth functional portion 126, and the pads 122 are electrically connected to the second functional portion 125 (second upper winding 125a). The second semiconductor element 12 of the semiconductor device A7 is obtained by integrating a drive element and an insulating element in a single chip.

In the semiconductor device A7, the first circuit including the third functional portion 116 of the first semiconductor element 11 and the second circuit including the fourth functional portion 126 of the second semiconductor element 12 are insulated by the first functional portion 115 of the first semiconductor element 11 and the second functional portion 125 of the second semiconductor element 12.

The method for manufacturing the semiconductor device A7 is the same as that of the semiconductor device A1. That is, the manufacturing method for the semiconductor device A7 is the same as that of the semiconductor device A1 (see FIG. 10), except for the following steps. First, the element mounting step S13 does not include the step for mounting the third semiconductor element 13 and the fourth semiconductor element 14. Second, the wire bonding step S14 does not include forming the bump-stacked bodies 2, the fourth wires 44, the fifth wires 45, the sixth wire 46 and the seventh wire 47.

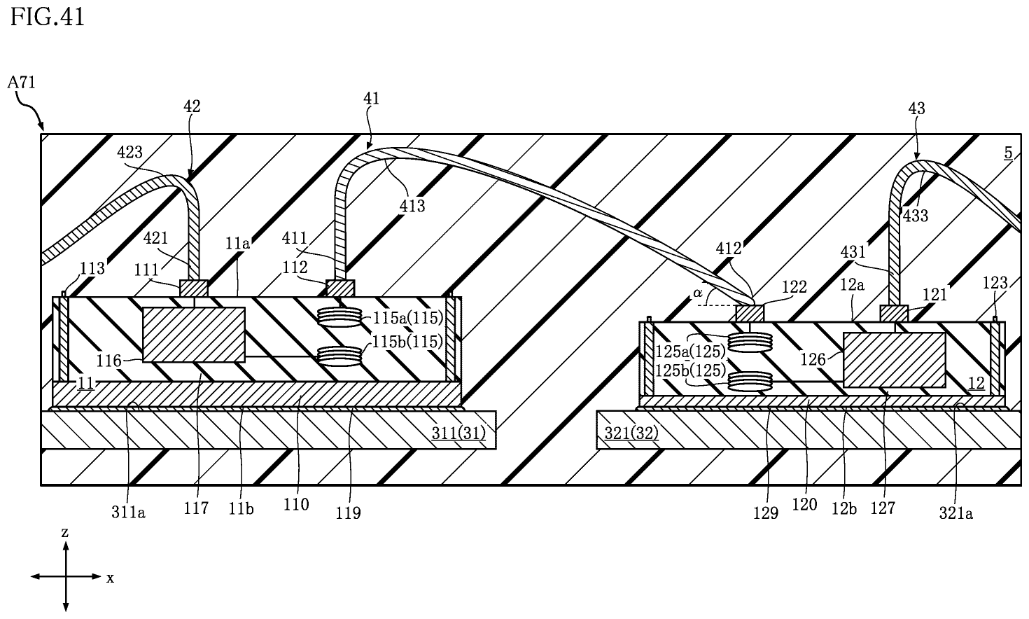

FIG. 41 shows a semiconductor device A71 according to a first variation of the seventh embodiment. FIG. 41 is a sectional view of a part of the semiconductor device A71, and the parts not shown may be configured in the same manner as the semiconductor device A7. The semiconductor device A71 does not include the bump-stacked bodies 2 and the thicknesses of the first semiconductor element 11 and the second semiconductor element 12 are different from each other. The first semiconductor element 11 is thicker than the second semiconductor element 12 as with the semiconductor devices A3 and A31.

Operative effects of the semiconductor devices A7 and A71 are as follows.

In the semiconductor devices A7 and A71, the bonding portion 411 of the first wire 41 is located differently from the bonding portion 412 of the first wire 41 in the thickness direction z. Thus, the first wire 41 has a margin to avoid proximity between the first wire 41 and the first semiconductor element 11 or the second semiconductor element 12. Therefore, the semiconductor devices A7 and A71 have an advantage that the occurrence of dielectric breakdown can be reduced. In addition, the semiconductor devices A7 and A71 may have a configuration in common with the semiconductor devices A1 to A61, thereby achieving the same effect as the semiconductor devices A1 to A61.

The seventh embodiment shows an example in which the first semiconductor element 11 includes the first functional portion 115 and the third functional portion 116 and the second semiconductor element 12 includes the second functional portion 125 and the fourth functional portion 126. However, the first semiconductor element 11 may not include the third functional portion 116 or the second semiconductor element 12 may not include the fourth functional portion 126.

In the above first to seventh embodiments (and their respective variations), the case in which the first semiconductor element 11 and the second semiconductor element 12 share equally the voltage difference between the first circuit and the second circuit and insulate them is basically described as an example. In other words, the case in which the first semiconductor element 11 and the second semiconductor element 12 have the same insulation ratio for the voltage difference between the first circuit and the second circuit is described as an example. Unlike this configuration, the insulation ratio of the first semiconductor element 11 and the second semiconductor element 12 may be different from each other with respect to the voltage difference between the first circuit and the second circuit. In this case, the number of insulative layers 1171 between the first upper winding 115a and the first lower winding 115b and the number of insulative layers 1271 between the second upper winding 125a and the second lower winding 125b may differ according to the insulation ratio between the first semiconductor element 11 and the second semiconductor element 12. For example, when the insulation ratio of the first semiconductor element 11 is greater than that of the second semiconductor element 12, the number of the insulative layers 1171 may be greater than the number of the insulative layers 1271. In such a manner, the insulation ratio of the first semiconductor element 11 and the second semiconductor element 12 is not limited in the semiconductor device of the present disclosure.

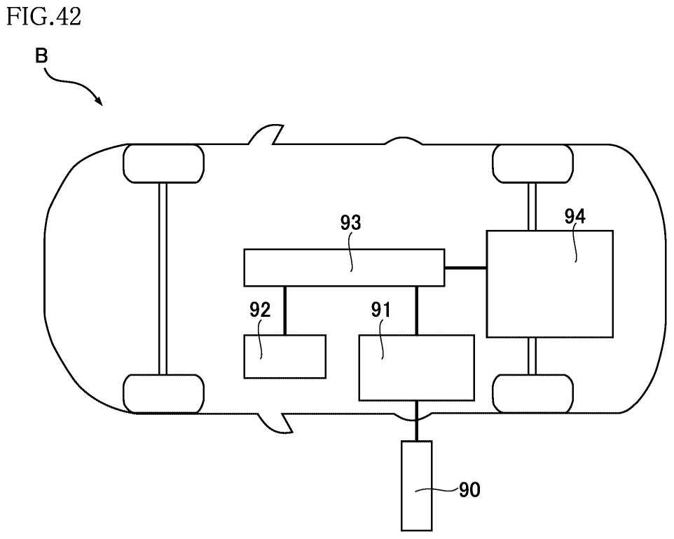

The semiconductor devices A1 to A71 (hereinafter referred to a semiconductor device of the present disclosure) may be installed in a vehicle B. FIG. 42 is an overview diagram of the vehicle B in which the semiconductor devices of the present disclosure are installed. The vehicle B is an electric vehicle (EV), for example.

In the illustrated example, vehicle B includes an AC-DC converter 91, a power receiving device 92, a storage battery 93, and a driving system 94. The semiconductor device of the present disclosure forms a part of the AC-DC converter 91. The vehicle B receives AC power from a charging facility, which is an AC power source installed outdoors or in similar environments. The AC-DC converter 91 converts the AC power to high-voltage DC power and feeds the high-voltage DC power to the storage battery 93. Alternatively, the vehicle B may be powered by an electromagnetic induction system from a non-contact charger installed in a parking lot or in similar environments. In this case, the storage battery 93 is powered from the power receiving device 92 by the non-contact charging system. The power stored in the storage battery 93 is fed to the driving system 94, which includes an inverter, an AC motor, and a transmission. The driving system 94 drives the vehicle B.

The semiconductor devices and the method for manufacturing the semiconductor devices according to the present disclosure are not limited to the embodiments described above. The specific configuration of each part of a semiconductor device and the method for manufacturing a semiconductor device according to the present disclosure may suitably be designed and changed in various manners.

The present disclosure includes the embodiments described in the following clauses.

### Clause 1.

A semiconductor device (A1-A21) comprising:
a first semiconductor element (11);
a second semiconductor element (12);
a first lead (31) electrically connected to the first semiconductor element (11);
a second lead (32) electrically connected to the second semiconductor element (12) and separated from the first lead (31);
a first wire (41) electrically connecting the first semiconductor element (11) and the second semiconductor element (12); and
at least one bump-stacked body (2) including a plurality of bumps (21) stacked in a thickness direction (z) of the first semiconductor element (11) one another,
wherein the first wire (41) includes a first end (411) overlapping with the first semiconductor element (11) and a second end (412) overlapping with the second semiconductor element (12) as viewed in the thickness direction (z), and
the at least one bump-stacked body (2) is located between the first semiconductor element (11) and the first end (411) or between the second semiconductor element (12) and the second end (412).

### Clause 2.

The semiconductor device (A1, A11, A21) according to clause 1, wherein the at least one bump-stacked body (2) is bonded to the second semiconductor element (12) and the second end (412), and
the second end (412) is located differently from the first end (411) in the thickness direction (z).
Clause 3.

The semiconductor device (A11) according to clause 2, wherein the second semiconductor element (12) includes a pad (122),
the at least one bump-stacked body (2) includes a first bump (21a), a second bump (21b), and a third bump (21c),
the first bump (21a) is in contact with the pad (122),
the second bump (21b) is in contact with the first bump (21a),
the third bump (21c) is in contact with the second bump (21b) and the second end (412), and
the first bump (21a) surrounds the second bump (21b) and the second bump (21b) surrounds the third bump (21c) as viewed in the thickness direction (z).

### Clause 4.

The semiconductor device (A2, A21) according to clause 1 or 2, wherein the at least one bump-stacked body (2) is bonded to the first semiconductor element (11) and the first end (411), and
the first end (411) is located differently from the second end (412) in the thickness direction (z).

### Clause 5.

The semiconductor device (A21) according to any one of clauses 1 to 3, wherein the at least one bump-stacked body (2) includes a first bump-stacked body (2a) and a second bump-stacked body (2b),
the first bump-stacked body (2a) is bonded to the first semiconductor element (11) and the first end (411),
the second bump-stacked body (2b) is bonded to the second semiconductor element (12) and the second end (412),
the number of bumps (21) in the first bump-stacked body (2a) is greater than the number of bumps (21) in the second bump-stacked body (2b), and
the first end (411) is located differently from the second end (412) in the thickness direction (z).

### Clause 6.

A semiconductor device (A3-A53) comprising:
a first semiconductor element (11);
a second semiconductor element (12);
a first lead (31) electrically connected to the first semiconductor element (11);
a second lead (32) electrically connected to the second semiconductor element (12) and separated from the first lead (31); and
a first wire (41) electrically connecting the first semiconductor element (11) and the second semiconductor element (12),
wherein the first wire (41) includes a first end (411) bonded to the first semiconductor element (11) and a second end (412) bonded to the second semiconductor element (12), and
the first end (411) is located differently from the second end (412) in the thickness direction (z) of the first semiconductor element (11).

### Clause 7.

The semiconductor device (A3, A31) according to clause 6, wherein the first semiconductor element (11) has a dimension in the thickness direction (z) greater than a dimension in the thickness direction (z) of the second semiconductor element (12).

### Clause 8.

The semiconductor device (A3, A31) according to clause 7, wherein the first
semiconductor element (11) includes a first semiconductor substrate (110),
the second semiconductor element (12) includes a second semiconductor substrate (120), and
the first semiconductor substrate (110) has a dimension in the thickness direction (z) greater than a dimension in the thickness direction (z) of the second semiconductor substrate (120).

### Clause 9.

The semiconductor device (A4) according to any one of clauses 6 to 8, further comprising a spacer (6),
wherein the spacer (6) is disposed between the first semiconductor element (11) and the first lead (31).

### Clause 9-1.

The semiconductor device (A41) according to any one of clauses 6 to 8, further comprising a first conductive bonding material (119) and a second conductive bonding material (129),
wherein the first conductive bonding material (119) is provided between the first semiconductor element (11) and the first lead (31),
the second conductive bonding material (129) is provided between the second semiconductor element (12) and the second lead (32), and
the first conductive bonding material (119) has a dimension in the thickness direction (z) greater than a dimension in the thickness direction (z) of the second conductive bonding material (129).

### Clause 10.

The semiconductor device (A4) according to clause 9, wherein the spacer (6) is electrically connected to the first lead (31).

### Clause 11.

The semiconductor device (A1-A71) according to any one of clauses 1 to 10 further comprising, a second wire (42),
wherein the second wire (42) includes a third end (421) bonded to the first semiconductor element (11) and a fourth end (422) opposite the third end (421), and
an internal angle (α) between the second end (412) and a horizontal plane is greater than an internal angle (β) between the fourth end (422) and a horizontal plane.

### Clause 12.

The semiconductor device (A1-A41) according to any one of clauses 1 to 11, wherein the first lead (31) includes a first island portion (311) on which the first semiconductor element (11) is mounted,
the second lead (32) includes a second island portion (321) on which the second semiconductor element (12) is mounted, and
the first island portion (311) overlaps with the second island portion (321) as viewed in a first direction (x) orthogonal to the thickness direction (z).

### Clause 13.

The semiconductor device (A1-A71) according to clause 12, further comprising a sealing resin (5) covering the first lead (31) and the second lead (32),
wherein the first lead (31) includes a covered portion (312a) covered by the sealing resin (5) and an exposed portion (312b) exposed from the sealing resin (5) and connected to the covered portion (312a), and
the covered portion (312a) includes at least one first terminal portion (312) connected to the first island portion (311) and the exposed portion (312b).

### Clause 14.

The semiconductor device (A12) according to clause 13, wherein the number of the at least one first terminal portion (312) is two,
the first island portion (311) includes two ends (3111) spaced apart from each other in the first direction (x), and
the two first terminal portions (312) are connected to the respective two ends (3111).

### Clause 15.

The semiconductor device (A1-A53) according to any one of clauses 11 to 14, further comprising a third semiconductor element (13) electrically connected to the first semiconductor element (11); and
a fourth semiconductor element (14) electrically connected to the second semiconductor element (12),
wherein the third semiconductor element (13) is supported by the first lead (31)
the fourth semiconductor element (14) is supported by the second lead (32), and
the fourth end (422) of the second wire (42) is bonded to the third semiconductor element (13).

### Clause 16.

The semiconductor device (A1-A53) according to clause 15, further comprising a third wire (43) connected to the second semiconductor element (12) and the fourth semiconductor element (14),
wherein the third wire (43) includes a fifth end (431) bonded to the second semiconductor element (12) and a sixth end (432) opposite the fifth end (431), and
an internal angle (α) between the second end (412) and a horizontal plane is greater than an internal angle (γ) between the sixth end (432) and a horizontal plane.

### Clause 17.

The semiconductor device (A1-A53) according to clause 15 or 16, wherein the third semiconductor element (13) includes a control circuit, and
the fourth semiconductor element (14) includes a drive circuit.

### Clause 18.

The semiconductor device (A1-A71) according to any one of clauses 1 to 17, wherein the first semiconductor element (11) includes a first functional portion (115) configured to transmit an electric signal in an insulated environment,
the second semiconductor element (12) includes a second functional portion (125) configured to transmit an electric signal in an insulated environment, and
the first functional portion (115) is electrically connected to the second functional portion (125) via the first wire (41).

### Clause 19.

The semiconductor device (A1-A71) according to clause 18, wherein the first functional portion (115) includes a first upper winding (115a) and a first lower winding (115b) spaced apart from each other in the thickness direction (z),
the second functional portion (125) includes a second upper winding (125a) and a second lower winding (125b) spaced apart from each other in the thickness direction (z), and
a distance between the first upper winding (115a) and the first lower winding (115b) in the thickness direction (z) is equal to the distance between the second upper winding (125a) and the second lower winding (125b) in the thickness direction (z).

### Clause 20.

The semiconductor device (A1-A71) according to clause 19, wherein the first semiconductor element (11) includes a plurality of first insulative layers (1171) stacked between the first upper winding (115a) and the first lower winding (115b),
the second semiconductor element (12) includes a plurality of second insulative layers (1271) stacked between the second upper winding (125a) and the second lower winding (125b),
the number of the plurality of first insulative layers (1171) is the same as the number of the plurality of second insulative layers (1271), and
a dimension in the thickness direction (z) of the plurality of first insulative layers (1171) is the same as a dimension in the thickness direction (z) of the plurality of second insulative layers (1271).

### Clause 21.

The semiconductor device (A1-A71) according to clause 19, wherein the potential of the first upper winding (115a) is the same as the potential of the second upper winding (125a), the potential of the first lower winding (115b) is the same as the potential of the first lead (31), and the potential of the second lower winding (125b) is the same as the potential of the second lead (32).

### Clause 22.

The semiconductor device (A7, A71) according to any one of clauses 18 to 21, further comprising a third lead (33) separated from the first lead (31) and the second lead (32),
wherein the first semiconductor element (11) includes a third functional portion (116) electrically connected to the second functional portion (125) across the first functional portion (115), and
the third functional portion (116) is electrically connected to the third lead (33).

### Clause 23.

The semiconductor device (A7, A71) according to clause 22, further comprising a fourth lead (34) separated from the first lead (31) and the second lead (32),
wherein the second semiconductor element (12) includes a fourth functional portion (126) electrically connected to the first functional portion (115) across the second functional portion (125), and
the fourth functional portion (126) is electrically connected to the fourth lead (34).

### Clause 24.

The semiconductor device (A5) according to any one of clauses 12 to 14, wherein the first island portion (311) includes a first mount face (311a) on which the first semiconductor element (11) is mounted,
the second island portion (321) includes a second mount face (321a) on which the second semiconductor element (12) is mounted, and
the first mount face (311a) does not overlap with the second mount face (321a) as viewed in the first direction (x).

### Clause 25.

The semiconductor device (A5) according to clause 24, wherein the first lead (31) includes a first bent portion that is bent as viewed in the first direction (x),
the second lead (32) includes a second bent portion that is bent as viewed in the first direction (x), and
an internal angle (θ1) of the first bent portion with respect to a horizontal plane is greater than an internal angle (θ2) of the second bent portion with respect to a horizontal plane.

### Clause 26.

The semiconductor device (A51) according to clause 24 or 25, wherein the first island portion (311) has a dimension in the thickness direction (z) greater than a dimension in the thickness direction (z) of the second island portion (321).

### Clause 27.

The semiconductor device (A52) according to clause 24 or 25, wherein the first island portion (311) includes a raised portion (311c) protruding in the thickness direction (z) at the first mount face (311a).

### Clause 28.

The semiconductor device (A53) according to clause 24 or 25, wherein the second island portion (321) includes a recessed portion (321c) recessed in the thickness direction (z) at the second mount face (321a).

### Clause 29.

A vehicle (B) comprising:
a driving system (94); and
the semiconductor device (A1-A71) according to any one of clauses 1 to 28,
wherein the semiconductor devices (A1-A71) are electrically connected to the driving system (94).

### REFERENCE NUMERALS

A1 to A71: Semiconductor devices B: Vehicle
11: First semiconductor element 11a: First obverse face
11b: First reverse face 110: First semiconductor substrate
111: Pad 112: Pad 113: First seal ring 115: First functional portion
115a: First upper winding 115b: First lower winding
116: Third functional portion 117: Laminated structure
1171: Insulative layer 118: Wiring portion 1181: Through wiring
1182: Lead-out wiring 119: First conductive bonding material
12: Second semiconductor element 12a: Second obverse face
12b: Second reverse face 120: Second semiconductor substrate
121: Pad 122: Pad 123: Second seal ring
125: Second functional portion 125a: Second upper winding
125b: Second lower winding 126: Fourth functional portion
127: Laminated structure 1271: Insulative layer
128: Wiring portion 1281: Through wiring
1282: Lead-out wiring 129: Second conductive bonding material
13: Third semiconductor element 13a: Third obverse face
13b: Third reverse face 131: Pad 139: Third conductive bonding material
14: Fourth semiconductor element 14a: Fourth obverse face
14b: Fourth reverse face 141: Pad 149: Fourth conductive bonding material
2: Bump-stacked body 2a: First bump-stacked body
2b: Second bump-stacked body 21: Bumps
21a-21c: First to third bumps 3: Conductive support member
31: First lead 311: First island portion 311a: First mount face
311b: First lead reverse face 311c: Raised portion
312: First terminal portion 312a: Covered portion
312a1: Outer portion 312a2: Inclined portion 312b: Exposed portion
32: Second lead 321: Second island portion 321a: Second mount face
321b: Second lead reverse face 321c: Recessed portion
322: Second terminal portion 322a: Covered portion
322a1: Outer portion 322a2: Inclined portion 322b: Exposed portion
33: Third lead 33A: Intermediate lead 33B: Outer lead
331: Covered portion 332: Exposed portion 34: Fourth lead
34A: Intermediate lead 34B: outer lead 341: Covered portion
342: Exposed portion 4: Connection member 41: First wire
411: Bonding portion (first end) 412: Bonding portion (second end)
413: Loop portion 42: Second wire
421: Bonding portion (third end) 422: Bonding portion (fourth end)
423: Loop portion 43: Third wire
431: Bonding portion (fifth end) 432: Bonding portion (sixth end)
433: Loop portion 44: Fourth wire 45: Fifth wire 46: Sixth wire
47: Seventh wire 5: Sealing resin 51: Top face 52: Bottom face
53: First side face 531: First upper portion 532: First lower portion
533: First intermediate portion 54: Second side face 541: Second upper portion
542: second lower portion 543: second intermediate portion
6: Spacer 81: Lead frame 810: Flat plate portion 811: First lead
811a: First island 811b: Support lead 812: Second lead 812a: Second island
812b: Support lead 813: Lead 814: Lead 815: Outer frame
816: Dam Bar 82: Resist 91: AC-DC converter 92: Power receiving device
93: Storage battery 94: Driving system

1. A semiconductor device comprising:
a first semiconductor element;
a second semiconductor element;
a first lead electrically connected to the first semiconductor element;
a second lead electrically connected to the second semiconductor element and separated from the first lead;
a first wire electrically connecting the first semiconductor element and the second semiconductor element; and
at least one bump-stacked body including a plurality of bumps stacked in a thickness direction of the first semiconductor element one another,
wherein the first wire includes a first end overlapping with the first semiconductor element and a second end overlapping with the second semiconductor element as viewed in the thickness direction, and
the at least one bump-stacked body is located between the first semiconductor element and the first end or between the second semiconductor element and the second end.

2. The semiconductor device according to claim 1, wherein the at least one bump-stacked body is bonded to the second semiconductor element and the second end, and
the second end is located differently from the first end in the thickness direction.

3. The semiconductor device according to claim 2, wherein the second semiconductor element includes a pad,
the at least one bump-stacked body includes a first bump a second bump and a third bump,
the first bump is in contact with the pad,
the second bump is in contact with the first bump,
the third bump is in contact with the second bump and the second end, and
the first bump surrounds the second bump and the second bump surrounds the third bump as viewed in the thickness direction.

4. The semiconductor device according to claim 1, wherein the at least one bump-stacked body is bonded to the first semiconductor element and the first end, and
the first end is located differently from the second end in the thickness direction.

5. The semiconductor device according to claim 1, wherein the at least one bump-stacked body includes a first bump-stacked body and a second bump-stacked body,
the first bump-stacked body is bonded to the first semiconductor element and the first end,
the second bump-stacked body is bonded to the second semiconductor element and the second end,
the number of bumps in the first bump-stacked body is greater than the number of bumps in the second bump-stacked body, and
the first end is located differently from the second end in the thickness direction.

6. The semiconductor device according to claim 1 further comprising, a second wire,
wherein the second wire includes a third end bonded to the first semiconductor element and a fourth end opposite the third end, and
an internal angle between the second end and a horizontal plane is greater than an internal angle between the fourth end and a horizontal plane.

7. The semiconductor device according to claim 6, wherein the first lead includes a first island portion on which the first semiconductor element is mounted,
the second lead includes a second island portion on which the second semiconductor element is mounted, and
the first island portion overlaps with the second island portion as viewed in a first direction orthogonal to the thickness direction.

8. The semiconductor device according to claim 7, further comprising a sealing resin covering the first lead and the second lead,
wherein the first lead includes a covered portion covered by the sealing resin and an exposed portion exposed from the sealing resin, and
the covered portion includes at least one first terminal portion connected to the first island portion and the exposed portion.

9. The semiconductor device according to claim 8, wherein the number of the at least one first terminal portion is two,
the first island portion includes two ends spaced apart from each other in the first direction, and
the two first terminal portions are connected to the respective two ends.

10. The semiconductor device according to claim 6, further comprising a third semiconductor element electrically connected to the first semiconductor element; and
a fourth semiconductor element electrically connected to the second semiconductor element,
wherein the third semiconductor element is supported by the first lead,
the fourth semiconductor element is supported by the second lead, and
the fourth end of the second wire is bonded to the third semiconductor element.

11. The semiconductor device according to claim 10, further comprising a third wire connected to the second semiconductor element and the fourth semiconductor element,
wherein the third wire includes a fifth end bonded to the second semiconductor element and a sixth end opposite the fifth end, and
an internal angle between the second end and a horizontal plane is greater than an internal angle between the sixth end and a horizontal plane.

12. The semiconductor device according to claim 10, wherein the third semiconductor element includes a control circuit, and
the fourth semiconductor element includes a drive circuit.

13. The semiconductor device according to claim 1, wherein the first semiconductor element includes a first functional portion configured to transmit an electric signal in an insulated environment,
the second semiconductor element includes a second functional portion configured to transmit an electric signal in an insulated environment, and
the first functional portion is electrically connected to the second functional portion via the first wire.

14. The semiconductor device according to claim 13, wherein the first functional portion includes a first upper winding and a first lower winding spaced apart from each other in the thickness direction,
the second functional portion includes a second upper winding and a second lower winding spaced apart from each other in the thickness direction, and
a distance between the first upper winding and the first lower winding in the thickness direction is equal to the distance between the second upper winding and the second lower winding in the thickness direction.

15. The semiconductor device according to claim 14, wherein the first semiconductor element includes a plurality of first insulative layers stacked between the first upper winding and the first lower winding,
the second semiconductor element includes a plurality of second insulative layers stacked between the second upper winding and the second lower winding,
the number of the plurality of first insulative layers is the same as the number of the plurality of second insulative layers, and
a dimension in the thickness direction of the plurality of first insulative layers is the same as a dimension in the thickness direction of the plurality of second insulative layers.
